(19) United States
(12) Patent Application Publication
(10) Pub. No.: US 2026/0095147 A1
(43) Pub. Date: Apr. 2, 2026

(54) ACOUSTIC WAVE DEVICE AND ACOUSTIC WAVE FILTER DEVICE

(71) Applicant: Murata Manufacturing Co., Ltd., Nagaokakyo-shi (JP)

(72) Inventors: Yuta ISHII, Nagaokakyo-shi (JP); Katsuya DAIMON, Nagaokakyo-shi (JP); Akihiro IYAMA, Nagaokakyo-shi (JP)

(21) Appl. No.: 19/413,061

(22) Filed: Dec. 9, 2025

Related U.S. Application Data
(63) Continuation of application No. PCT/JP2024/021585, filed on Jun. 13, 2024.

(30) Foreign Application Priority Data
Jun. 13, 2023 (JP) 2023-097131

(51) Int. Cl. H03H 9/13; H03H 9/54

(52) U.S. Cl. CPC H03H 9/133; H03H 9/54

(57) ABSTRACT

An acoustic wave device includes a piezoelectric layer including a first main surface and a second main surface facing the first main surface in a first direction, an IDT electrode on at least one of the first main surface and the second main surface of the piezoelectric layer and including electrode fingers arranged in an arrangement direction, a reflector adjacent to the IDT electrode in the arrangement direction of the electrode fingers, a support that faces the second main surface of the piezoelectric layer and includes an acoustic reflection portion on a side of the second main surface of the piezoelectric layer, and a load film provided in a region overlapping with the reflector in a plan view from the first direction. When a thickness of the piezoelectric layer is d and a distance between centers of the adjacent electrode fingers is p, d/p is about 0.5 or less.

### CROSS REFERENCE TO RELATED APPLICATIONS

This application claims the benefit of priority to Japanese Patent Application No. 2023-097131 filed on Jun. 13, 2023 and is a Continuation Application of PCT Application No. PCT/JP2024/021585 filed on Jun. 13, 2024. The entire contents of each application are hereby incorporated herein by reference.

### BACKGROUND OF THE INVENTION

### 1. Field of the Invention

The present invention relates to acoustic wave devices and acoustic wave filter devices.

### 2. Description of the Related Art

Japanese Unexamined Patent Application Publication No. 2022-524136 and U.S. Pat. No. 11,349,450 each describe an acoustic wave device.

### SUMMARY OF THE INVENTION

In the acoustic wave devices described in Japanese Unexamined Patent Application Publication No. 2022-524136 and U.S. Pat. No. 11,349,450, leakage of acoustic waves may occur in an arrangement direction of electrode fingers.

Example embodiments of the present invention provide acoustic wave devices and acoustic wave filter devices each capable of reducing or preventing leakage of acoustic waves.

An acoustic wave device according to an example embodiment of the present invention includes a piezoelectric layer including a first main surface and a second main surface facing the first main surface in a first direction, an IDT electrode that is provided on at least one of the first main surface and the second main surface of the piezoelectric layer and that includes a plurality of electrode fingers arranged in an arrangement direction, a reflector adjacent to the IDT electrode in the arrangement direction, a support that faces the second main surface of the piezoelectric layer and that has an acoustic reflection portion on a side of the second main surface of the piezoelectric layer, and a load film provided in a region overlapping with the reflector in a plan view from the first direction. When a thickness of the piezoelectric layer is d and a distance between centers of the adjacent electrode fingers is p, d/p is about 0.5 or less.

An acoustic wave filter device according to another example embodiment of the present invention includes at least one resonator connected thereto, in which the resonator is the acoustic wave device described above.

With the acoustic wave devices and the acoustic wave filter devices according to example embodiments of the present invention, leakage of acoustic waves can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view showing an acoustic wave device according to a first example embodiment of the present invention.

FIG. 2 is a cross-sectional view taken along line II-II′ of FIG. 1.

FIG. 3 is a schematic cross-sectional view for explaining a bulk wave in the first-order thickness-shear mode propagating through a piezoelectric layer of the first example embodiment of the present invention.

FIG. 4 is a schematic cross-sectional view for explaining the amplitude direction of the bulk wave in the first-order thickness-shear mode propagating through the piezoelectric layer of the first example embodiment of the present invention.

FIG. 5 is a graph for explaining an example of the resonance characteristics of the acoustic wave device of the first example embodiment of the present invention.

FIG. 6 is a graph for explaining the relationship between d/2p and fractional band width of a resonator, in the acoustic wave device of the first example embodiment, where p is the distance between the centers of adjacent electrodes or the average distance of distances between the centers of the adjacent electrodes, and d is the average thickness of the piezoelectric layer.

FIG. 7 is a plan view showing an example in which one pair of electrodes is provided in the acoustic wave device of the first example embodiment of the present invention.

FIG. 8 is a reference graph showing one example of the resonance characteristics of the acoustic wave device according to the first example embodiment of the present invention.

FIG. 9 is a graph for explaining the relationship between the fractional band width in a case where a large number of acoustic wave resonators are configured and a phase rotation amount of impedance of spurious signal normalized by 180 degrees as the magnitude of spurious signal, in the acoustic wave device according to the first example embodiment of the present invention.

FIG. 10 is a graph for explaining the relationship between d/2p, a metallization ratio MR, and the fractional band width.

FIG. 11 is a graph for explaining a map of the fractional band width for the Euler angles (0°, θ, ψ) of lithium niobate when d/p is brought as close to zero as possible.

FIG. 12 is an enlarged cross-sectional view of a region A shown in FIG. 2.

FIG. 13 is a graph for explaining one example of admittance characteristics of the acoustic wave device according to the first example embodiment of the present invention.

FIG. 14 is a graph for explaining the distribution of vibration modes of the acoustic wave device according to the first example embodiment of the present invention.

FIG. 15 is a graph for explaining the distribution of vibration modes of an acoustic wave device according to a comparative example.

FIG. 16 is a cross-sectional view showing an acoustic wave device according to a first modification of the first example embodiment of the present invention.

FIG. 17 is a cross-sectional view showing an acoustic wave device according to a second modification of the first example embodiment of the present invention.

FIG. 18 is a cross-sectional view showing an acoustic wave device according to a third modification of the first example embodiment of the present invention.

FIG. 19 is a cross-sectional view showing an acoustic wave device according to a fourth modification of the first example embodiment of the present invention.

FIG. 20 is a cross-sectional view showing an acoustic wave device according to a fifth modification of the first example embodiment of the present invention.

FIG. 21 is a cross-sectional view showing an acoustic wave device according to a sixth modification of the first example embodiment of the present invention.

FIG. 22 is a plan view showing an acoustic wave device according to a second example embodiment of the present invention.

FIG. 23 is a cross-sectional view taken along line XXIII-XXIII′ of FIG. 22.

FIG. 24 is a cross-sectional view showing an acoustic wave device according to a seventh modification of the second example embodiment of the present invention.

FIG. 25 is a plan view showing an acoustic wave device according to a third example embodiment of the present invention.

FIG. 26 is a circuit diagram showing an acoustic wave device according to a fourth example embodiment of the present invention.

FIG. 27 is a cross-sectional view showing an acoustic wave device according to an eighth modification of an example embodiment of the present invention.

FIG. 28 is a cross-sectional view showing an acoustic wave device according to a ninth modification of an example embodiment of the present invention.

FIG. 29 is a graph for explaining one example of admittance characteristics of an acoustic wave device according to a tenth modification of an example embodiment of the present invention.

FIG. 30 is a graph for explaining one example of impedance phases in a high-order mode.

### DETAILED DESCRIPTION OF THE EXAMPLE EMBODIMENTS

Example embodiments of the present disclosure will be described below in detail with reference to the accompanying drawings. Note that the present disclosure is not limited to such example embodiments. It should be noted that example embodiments described in the present disclosure are exemplary, and that, in modifications, a second example embodiment and subsequent example embodiments, in which partial replacement or combination of configurations is possible therebetween, the descriptions of matters common to a first example embodiment will be omitted, and only different points will be described. In particular, similar effects by similar configurations will not be referred to one by one in each example embodiment.

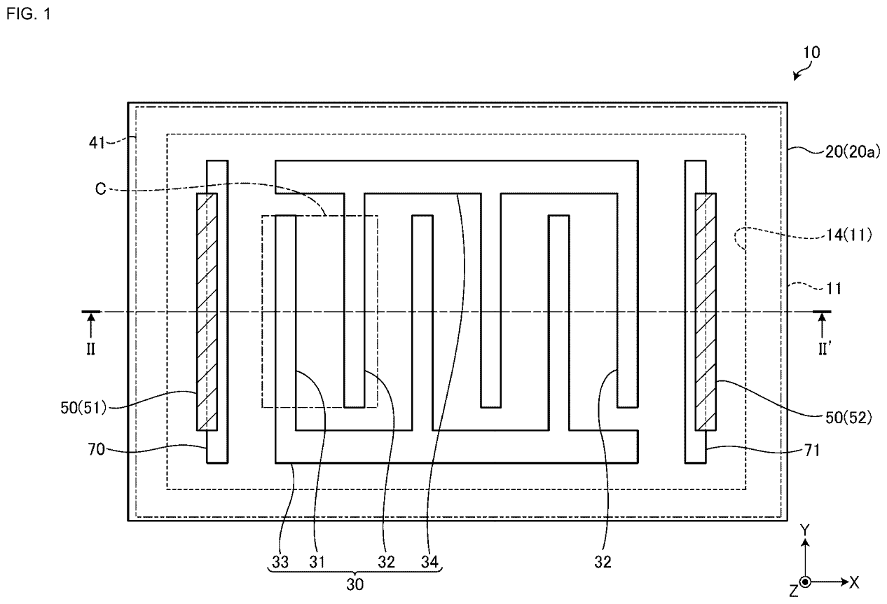

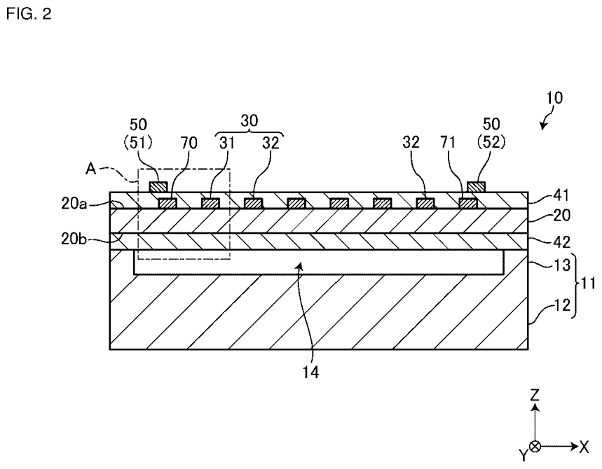

FIG. 1 is a plan view showing an acoustic wave device according to a first example embodiment. FIG. 2 is a cross-sectional view taken along line II-II′ of FIG. 1. Note that, in FIG. 1, a load film 50 is hatched to make the drawing easier to see. Further, in FIG. 1, a first protective film 41 is indicated by a two-dot chain line.

As shown in FIGS. 1 and 2, an acoustic wave device 10 according to the first example embodiment includes a piezoelectric layer 20, an IDT electrode 30, reflectors 70 and 71, a support substrate 11, the first protective film 41, a second protective film 42, and the load film 50. As shown in FIG. 2, in the acoustic wave device 10, the second protective film 42, the piezoelectric layer 20, the IDT electrode 30, the reflectors 70 and 71, the first protective film 41, and the load film 50 are laminated in this order on the support substrate 11.

The piezoelectric layer 20 has a flat plate shape, and has a first main surface 20a, and a second main surface 20b opposite to the first main surface 20a. The piezoelectric layer 20 includes lithium niobate. Alternatively, the piezoelectric layer 20 may include lithium tantalate. In the first example embodiment, the cut-angle of the lithium niobate or lithium tantalate is Z-cut. The cut-angle of the lithium niobate or lithium tantalate may alternatively be rotated Y-cut or X-cut. Preferably, the piezoelectric layer 20 has a propagation direction of about ±30° with respect to Y propagation and X propagation, for example. Preferably, the piezoelectric layer 20 includes lithium niobate or lithium tantalate, and has a cut-angle of 120°±10° rotated Y-cut or 90°±10° rotated Y-cut, for example.

The thickness of the piezoelectric layer 20 is not particularly limited, but is preferably about 50 nm or more and about 1000 nm or less in order to effectively excite a first-order thickness-shear mode, for example. The film thickness of the piezoelectric layer 20 according to the first example embodiment is, for example, about 180 nm.

The interdigital transducer (IDT) electrode 30 is provided on the first main surface 20a of the piezoelectric layer 20. As shown in FIG. 1, the IDT electrode 30 includes electrode fingers 31 and 32 and busbar electrodes 33 and 34. A plurality of electrode fingers 31 extend in the Y direction, and one end side of the electrode fingers 31 in the extending direction is connected to the busbar electrode 33. A plurality of electrode fingers 32 extend in the Y direction, and the other end side of the electrode fingers 32 in the extending direction is connected to the busbar electrode 34. The plurality of electrode fingers 31 and the plurality of electrode fingers 32 are alternately arranged in the X direction with an interval. The busbar electrode 33 and the busbar electrode 34 extend in the X direction, and are disposed separately from each other in the Y direction. The plurality of electrode fingers 31 and 32 are arranged between the busbar electrode 33 and the busbar electrode 34.

In the following description, the thickness direction of the piezoelectric layer 20 may be referred to as the Z direction, the extending direction of the electrode fingers 31 and 32 may be referred to as the Y direction, and the arrangement direction of the electrode fingers 31 and 32 may be referred to as the X direction. Further, in the following description, the plan view indicates an arrangement relationship when viewed from a direction perpendicular to the first main surface 20a of the piezoelectric layer 20.

The distance between the centers of the electrode fingers 31 and 32 (hereinafter referred to as electrode-to-electrode pitch) is preferably within the range of about 1 μm or more and about 10 μm or less, for example. The electrode-to-electrode pitch is a distance obtained by connecting the center of the width dimension of the electrode finger 31 in a direction perpendicular to the extending direction of the electrode finger 31 and the center of the width dimension of the electrode finger 32 in a direction perpendicular to the extending direction of the electrode finger 32. The width of the electrode fingers 31 and 32 (hereinafter referred to as electrode width), i.e., the dimension of the electrode fingers 31 and 32 in a direction perpendicular to the extending direction of the electrode fingers 31 and 32, is preferably within the range of about 150 nm or more and about 1000 nm or less, for example.

Further, when at least one of the number of electrode fingers 31 and the number of electrode fingers 32 is more than one (i.e., when one pair of electrode fingers 31 and 32 is defined as one electrode set, there are 1.5 or more sets of electrode sets), the electrode-to-electrode pitch of the electrode fingers 31 and 32 means the average value of the distances between the centers of any adjacent electrode fingers 31 and 32, among the electrode fingers 31 and 32 of the 1.5 or more sets of electrode sets.

In the first example embodiment, since a Z-cut piezoelectric layer is used, the direction perpendicular to the extending direction of the electrode fingers 31 and 32 is the direction perpendicular to the polarization direction of the piezoelectric layer 20. Such configuration does not apply when a piezoelectric material having any of other cut-angles is used as the piezoelectric layer 20. Here, the term “perpendicular to” is not limited to a case where one object is strictly perpendicular to another object, but may include a case where one object is substantially perpendicular to another object (the angle between a direction perpendicular to the extending direction of the electrode fingers 31 and 32 and the polarization direction is, for example, about 90°±10°).

The IDT electrode 30 (the electrode fingers 31 and 32 and the busbar electrodes 33 and 34) is made of a suitable metal or alloy such as aluminum or an aluminum-copper alloy. In the first example embodiment, the IDT electrode 30 has a structure in which an aluminum film is laminated on a titanium film. Note that an adhesion layer other than the titanium film may alternatively be used.

More specifically, the electrode configuration of the IDT electrode 30 is a multilayer film obtained by laminating the layers of titanium/aluminum-copper alloy/titanium/aluminum-copper alloy from the piezoelectric layer 20 side, and the respective film thicknesses of these layers are about 12 nm/70 nm/18 nm/12 nm, for example. The total number of the electrode fingers 31 and 32 of the IDT electrode 30 is 51. The electrode-to-electrode pitch of the electrode fingers 31 and 32 is about 2.38 μm, and the electrode widths of the electrode fingers 31 and 32 are each about 0.6 μm, for example.

Here, an intersecting region C (excitation region) shown in FIG. 1 is a region where the electrode fingers 31 and 32 overlap with each other when viewed in the X direction. The length of the intersecting region C is a dimension of the intersecting region C in the extending direction of the electrode fingers 31 and 32. In the present example embodiment, the length of the intersecting region C is, for example, about 40 μm.

During the driving, an AC voltage is applied between the plurality of electrode fingers 31 and the plurality of electrode fingers 32. More specifically, an AC voltage is applied between the busbar electrode 33 and the busbar electrode 34. As a result, it is possible to obtain resonance characteristics using a bulk wave in the first-order thickness-shear mode excited in the piezoelectric layer 20.

In the acoustic wave device 10, when the thickness of the piezoelectric layer 20 is d and the electrode-to-electrode pitch of the plurality of pairs of electrode fingers 31 and 32 is p, d/p is set to about 0.5 or less, for example. Therefore, the bulk wave in the first-order thickness-shear mode is effectively excited, and good resonance characteristics can be obtained. More preferably, d/p is set to about 0.24 or less, and in such a case even better resonance characteristics can be obtained.

Since the acoustic wave device 10 of the first example embodiment has the above-described configuration, even if the number of pairs of electrode fingers 31 and 32 is reduced for miniaturization purposes, a decrease in Q value is unlikely to occur. This is because propagation loss is small in a resonator using a bulk wave in the first-order thickness-shear mode.

The reflectors 70 and 71 are provided on the first main surface 20a of the piezoelectric layer 20, on the same layer as the IDT electrode 30. The reflectors 70 and 71 are multilayer films having the same electrode configuration as that of the IDT electrode 30, and include the same material as that of the IDT electrode 30. However, the reflectors 70 and 71 do not have to have the same electrode configuration as that of the IDT electrode 30 and include the same material as that of the IDT electrode 30, but may have different electrode configuration and include different material from that of the IDT electrode 30.

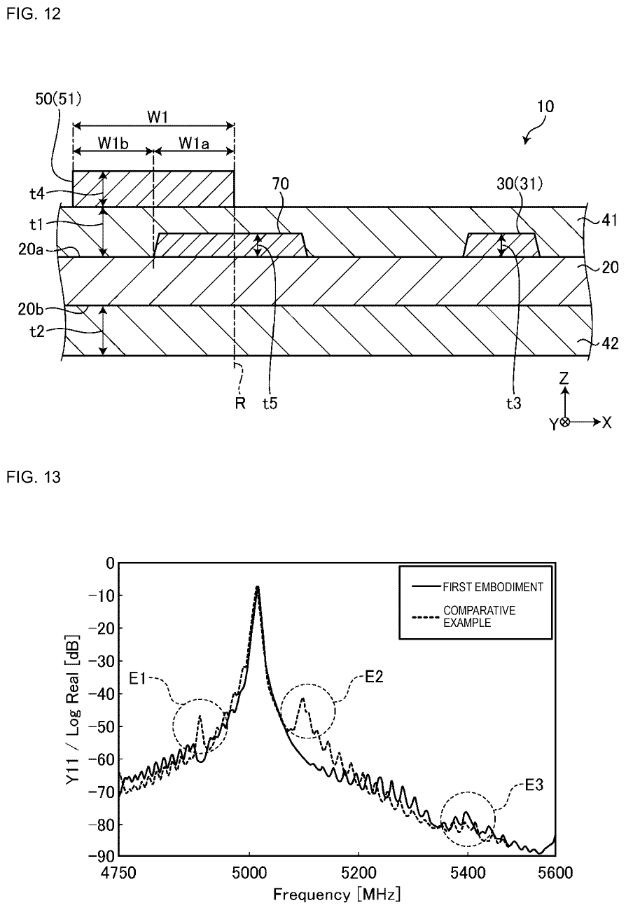

The reflectors 70 and 71 are disposed adjacent to the IDT electrode 30 in the arrangement direction of the plurality of electrode fingers 31 and 32, with a space from the IDT electrode 30. In the present example embodiment, the reflectors 70 and 71 each have one electrode finger, and extend along the extending direction of the electrode fingers 31 and 32. On one side (the left side in FIGS. 1 and 2) of the arrangement direction of the plurality of electrode fingers 31 and 32, the reflector 70 is disposed adjacent to the IDT electrode 30 with a space from the IDT electrode 30. On the other side (the right side in FIGS. 1 and 2) of the arrangement direction of the plurality of electrode fingers 31 and 32, on a side opposite to the reflector 70, the reflector 71 is disposed adjacent to the IDT electrode 30 with a space from the IDT electrode 30. The IDT electrode 30 is disposed between the reflector 70 and the reflector 71. The detailed configuration of the reflectors 70 and 71 will be described later with reference to FIG. 12.

The first protective film 41 is provided on the first main surface 20a of the piezoelectric layer 20 to cover the IDT electrode 30 and the reflectors 70 and 71. The second protective film 42 is provided on the second main surface 20b of the piezoelectric layer 20. The first protective film 41 and the second protective film 42 include silicon oxide. In addition to silicon oxide, the first protective film 41 and the second protective film 42 may alternatively include other suitable insulating material, such as silicon nitride or alumina. The film thickness of each of the first protective film 41 and the second protective film 42 is larger than the film thickness of the IDT electrode 30. The film thickness of each of the first protective film 41 and the second protective film 42 is about 142 nm, for example. Note that it is sufficient to provide at least one of the first protective film 41 and the second protective film 42. For example, an example embodiment of the present invention also includes a configuration in which the first protective film 41 is provided, but the second protective film 42 is not provided.

The load film 50 is provided on the first protective film 41. The load film 50 is provided in a region overlapping with the reflectors 70 and 71. The load film 50 is not provided in a region overlapping with the plurality of electrode fingers 31 and 32 located between the reflector 70 and the reflector 71.

A portion of the load film 50 overlapping with the reflector 70 is referred to as a first extending portion 51, and a portion of the load film 50 overlapping with the reflector 71 is referred to as a second extending portion 52. The first extending portion 51 and the second extending portion 52 are disposed separately from each other in the arrangement direction of the plurality of electrode fingers 31 and 32, and the plurality of electrode fingers 31 and 32 are disposed between the first extending portion 51 and the second extending portion 52. The first extending portion 51 overlaps with a portion of the reflector 70, and extends along the extending direction of the reflector 70. Further, the second extending portion 52 overlaps with a portion of the reflector 71, and extends along the extending direction of the reflector 71. The detailed configuration of the load film 50 will be described later with reference to FIGS. 12 and 13.

The support substrate 11 (support) is disposed to face the second main surface 20b of the piezoelectric layer 20. The support substrate 11 includes a cavity portion 14 (space portion) on a surface facing the second main surface 20b of the piezoelectric layer 20. More specifically, the support substrate 11 has a bottom portion 12, and a wall portion 13 with a frame shape on an upper surface of the bottom portion 12. The cavity portion 14 is located in a space surrounded by the bottom portion 12 and the wall portion 13. The piezoelectric layer 20 is laminated on an upper surface of the wall portion 13 of the support substrate 11 with the second protective film 42 interposed therebetween. As described above, the acoustic wave device 10 has a so-called membrane structure in which the cavity portion 14 (space portion) is provided on the second main surface 20b side of the piezoelectric layer 20. Note that the support may include the support substrate 11 and an intermediate layer (insulating layer). That is, the support substrate 11 may be indirectly laminated on the second main surface 20b of the piezoelectric layer 2. In such a case, the support substrate 11 and the intermediate layer may have a frame shape to define the cavity portion 14. Alternatively, a recess may be provided in the intermediate layer to define the cavity portion 14.

The cavity portion 14 is provided so as not to disturb the vibration of the intersecting region C of the piezoelectric layer 20. The second protective film 42 is provided to cover the opening of the cavity portion 14. However, as described above, the second protective film 42 does not have to be provided. In such a case, the support substrate 11 may be directly laminated on the second main surface 20b of the piezoelectric layer 20. Alternatively, an example embodiment of the present invention may include a configuration in which the second protective film 42 is provided in a region between the upper surface of the wall portion 13 and the second main surface 20b of the piezoelectric layer 20, and not provided in a region overlapping with the cavity portion 14.

The support substrate 11 includes silicon. The plane direction of the silicon on the piezoelectric layer 20 side may be (100), (110), or be (111). Preferably, silicon having a high resistivity of about 4 kΩ or more is used, for example. The support substrate 11 may also include a suitable insulating material or semiconductor material. For example, a piezoelectric material, a ceramic, a dielectric material, or a semiconductor may be used as the material of the support substrate 11, in which examples of the piezoelectric material include aluminum oxide, lithium tantalate, lithium niobate, and quartz; examples of the ceramic include alumina, magnesia, sapphire, silicon nitride, aluminum nitride, silicon carbide, zirconia, cordierite, mullite, steatite, and forsterite; examples of the dielectric material include diamond and glass; and examples of the semiconductor include gallium nitride.

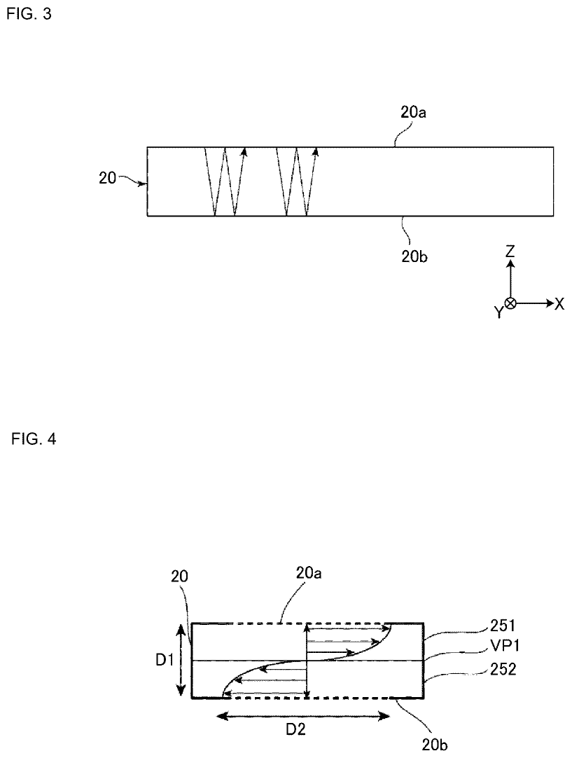

FIG. 3 is a schematic cross-sectional view for explaining the bulk wave in the first-order thickness-shear mode propagating through the piezoelectric layer of the first example embodiment. FIG. 4 is a schematic cross-sectional view for explaining the amplitude direction of the bulk wave in the first-order thickness-shear mode propagating through the piezoelectric layer of the first example embodiment.

As shown in FIG. 3, in the acoustic wave device 10 of the first example embodiment, since the vibration displacement is in the thickness-shear direction, the wave propagates and resonates substantially in a direction connecting the first main surface 20a and the second main surface 20b of the piezoelectric layer 20, i.e., in the Z direction. That is, the X-direction component of the wave is remarkably smaller than the Z-direction component. The resonance characteristics are obtained by the propagation of the wave in the Z direction.

As shown in FIG. 4, the amplitude direction of the bulk wave in the first-order thickness-shear mode in a first region 251 included in the intersecting region C (see FIG. 1) of the piezoelectric layer 20 is opposite to the amplitude direction in a second region 252 included in the intersecting region C. FIG. 4 schematically shows a bulk wave obtained when a voltage is applied between the electrode finger 31 and the electrode finger 32 such that the electrode finger 32 has a higher potential than the electrode finger 31. Here, a virtual plane VP1 is a plane that is perpendicular to the thickness direction of the piezoelectric layer 20, and that divides the piezoelectric layer 20 into two regions. The first region 251 is a region between the virtual plane VP1 and the first main surface 20a in the intersecting region C. The second region 252 is a region between the virtual plane VP1 and the second main surface 20b in the intersecting region C.

At least one pair of electrodes including the electrode fingers 31 and 32 is disposed in the acoustic wave device 10. However, since such electrode pair including the electrode fingers 31 and 32 does not propagate the wave in the X direction, it is not necessary to include more than one electrode pair including the electrode fingers 31 and 32. That is, the number of pairs of electrodes is not limited as long as at least one pair of electrodes is provided.

For example, the electrode fingers 31 are electrodes connected to a hot potential, and the electrode fingers 32 are electrodes connected to a ground potential. Alternatively, the electrode fingers 31 may be connected to the ground potential, and the electrode fingers 32 may be connected to the hot potential. In the first example embodiment, as described above, the at least one pair of electrodes are an electrode connected to the hot potential and an electrode connected to the ground potential, and no floating electrode is provided.

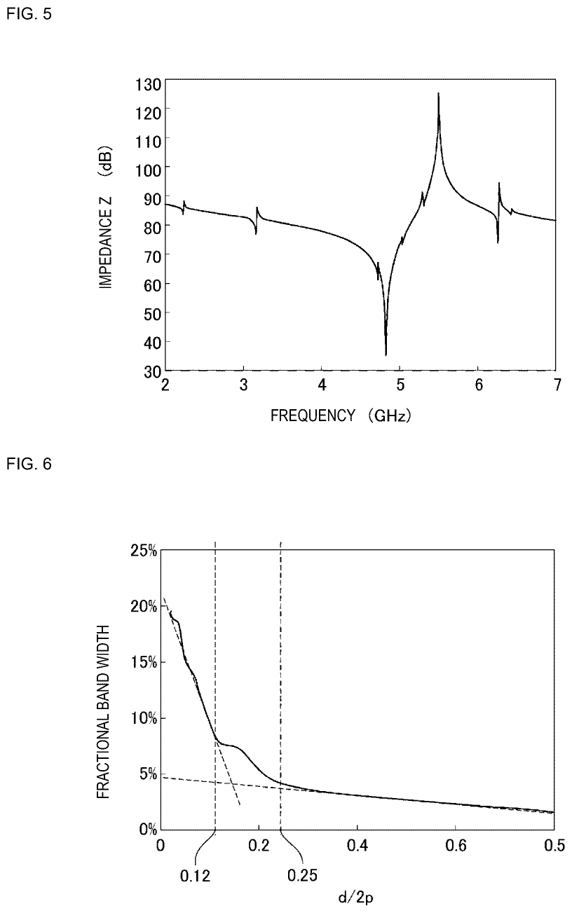

FIG. 5 is a graph for explaining an example of the resonance characteristics of the acoustic wave device of the first example embodiment. The design parameters of the acoustic wave device 10 having the resonance characteristics shown in FIG. 5 are as follows.

The piezoelectric layer 20 includes lithium niobate with Euler angles (0°, 0°, 90°), for example. The thickness of the piezoelectric layer 20 is about 400 nm, for example.

The length of the intersecting region C is about 40 μm, for example. The number of pairs of electrodes including the electrode fingers 31 and 32 is 21 pairs, for example. The electrode-to-electrode pitch between the electrode fingers 31 and 32 is about 3 μm, for example. The width of each of the electrode fingers 31 and 32 is about 500 nm, for example. d/p is about 0.133, for example.

The first protective film 41 and the second protective film 42 are each a silicon oxide film with a thickness of about 1 μm, for example.

The support substrate 11 includes silicon.

In the first example embodiment, the electrode-to-electrode pitch of the electrode pairs including the electrode fingers 31 and 32 is equal among all the plurality of pairs. That is, the electrode fingers 31 and the electrode fingers 32 are disposed at equal pitches.

It is known from FIG. 5 that good resonance characteristics with a fractional band width of about 12.5% are obtained, for example.

Incidentally, when the thickness of the piezoelectric layer 20 is d and the electrode-to-electrode pitch between the electrode fingers 31 and 32 is p, d/p is about 0.5 or less, more preferably about 0.24 or less in the first example embodiment, for example. The details about this will be described with reference to FIG. 6.

FIG. 6 is a graph for explaining the relationship between d/2p and the fractional band width of a resonator, in the acoustic wave device of the first example embodiment, where p is the distance between the centers of adjacent electrodes or the average distance of distances between the centers of the adjacent electrodes, and d is the average thickness of the piezoelectric layer. FIG. 6 is obtained in the same manner as the acoustic wave device having the resonance characteristics shown in FIG. 5. However, in FIG. 6, a plurality of acoustic wave devices are obtained by changing d/2p.

As shown in FIG. 6, when d/2p exceeds about 0.25, that is, when d/p>about 0.5, the fractional band width is less than about 5% even when d/p is adjusted. In contrast, when d/2p≤about 0.25, that is, when d/p≤about 0.5, the fractional band width can be increased to about 5% or more by changing d/p within such a range, that is, a resonator having a high coupling coefficient can be configured. Further, when d/2p is about 0.12 or less, that is, when d/p is about 0.24 or less, the fractional band width can be increased to about 7% or more, for example. In addition, when d/p is adjusted within such a range, a resonator having a wider fractional band width can be obtained, and a resonator having a higher coupling coefficient can be realized. Therefore, it is understood that when d/p is about 0.5 or less, for example, a resonator having a high coupling coefficient using the bulk wave in the first-order thickness-shear mode can be configured.

As for the thickness d of the piezoelectric layer 20, if the piezoelectric layer 20 has thickness variations, a value obtained by averaging the thicknesses may be used as the thickness d of the piezoelectric layer 20.

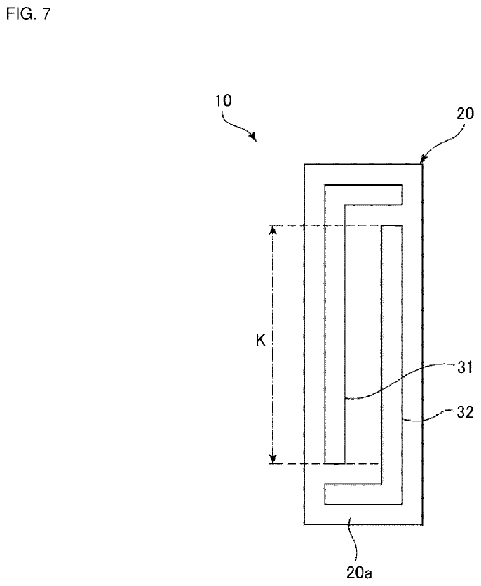

FIG. 7 is a plan view showing an example in which one pair of electrodes is provided in the acoustic wave device of the first example embodiment. In the acoustic wave device 10, one pair of electrodes including the electrode fingers 31 and 32 is provided on the first main surface 20a of the piezoelectric layer 20. K in FIG. 7 represents an intersecting width. As described above, in the acoustic wave device 10 according to an example embodiment of the present disclosure, the number of pairs of electrodes may be one. Even in such a case, if the above d/p is about 0.5 or less, for example, the bulk wave in the first-order thickness-shear mode can be effectively excited.

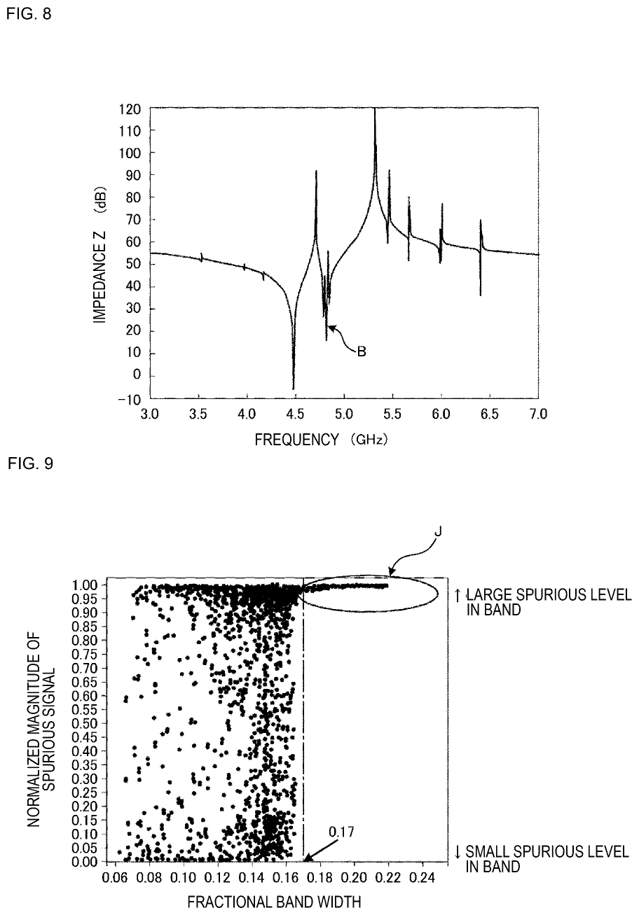

In the acoustic wave device 10, it is preferable that a metallization ratio MR of the adjacent electrode fingers 31 and 32 with respect to the intersecting region C satisfies MR≤about 1.75 (d/p)+0.075, for example. In such a case, the spurious signal can be effectively reduced. The details about this will be described with reference to FIGS. 8 and 9.

FIG. 8 is a reference graph showing one example of the resonance characteristics of the acoustic wave device according to the first example embodiment. As shown in FIG. 8, a spurious signal indicated by an arrow B appears between a resonant frequency and an anti-resonant frequency. In such an example, d/p=about 0.08 and the Euler angles of lithium niobate are (0°, 0°, 90°), for example. Also, the metallization ratio MR is set to about 0.35, for example.

The metallization ratio MR will be described with reference to FIG. 1. In the electrode structure shown in FIG. 1, when focusing on one pair of electrode fingers 31 and 32, it is assumed that only such one pair of electrode fingers 31 and 32 is provided. In such a case, a portion surrounded by a one-dot chain line is the intersecting region C. When the electrode finger 31 and the electrode finger 32 are viewed in a direction perpendicular to the extending direction of the electrode finger 31 and the electrode finger 32, i.e., in a direction in which the electrode finger 31 and the electrode finger 32 face each other, the intersecting region C includes a region of the electrode finger 31 in which the electrode finger 31 overlaps with the electrode finger 32, a region of the electrode finger 32 in which the electrode finger 32 overlaps with the electrode finger 31, and a region between the electrode finger 31 and the electrode finger 32 in which the electrode finger 31 and the electrode finger 32 overlap with each other. The area of the electrode finger 31 and the electrode finger 32 in the intersecting region C with respect to the area of the intersecting region C is the metallization ratio MR. That is, the metallization ratio MR is a ratio of the area of the metallization portion to the area of the intersecting region C.

In the case where a plurality of pairs of electrode fingers 31 and 32 are provided, the ratio of the metallization portion included in the total intersecting regions C to the total area of the intersecting regions C just needs to be set for MR.

FIG. 9 is a graph for explaining the relationship between the fractional band width in a case where a large number of acoustic wave resonators are configured and a phase rotation amount of impedance of spurious signal normalized by 180 degrees as the magnitude of spurious signal, in the acoustic wave device according to the first example embodiment. As for the fractional band width, it is adjusted by variously changing the film thickness of the piezoelectric layer 20 and the dimensions of the electrode finger 31 and the electrode finger 32. FIG. 9 shows the result in a case where the piezoelectric layer 20 made of lithium niobate of the Z-cut is used. However, the same tendency is observed in a case where the piezoelectric layer 20 of any of other cut-angles is used.

In a region surrounded by an ellipse J in FIG. 9, the magnitude of the spurious signal is large at 1.0. It is known from FIG. 9 that, when the fractional band width exceeds about 0.17, i.e., when the fractional band width exceeds about 17%, for example, a large spurious signal having a high spurious level at 1 or more appears in the pass band even if parameters of the fractional band width are changed. That is, as shown in the resonance characteristics of FIG. 8, a large spurious signal indicated by the arrow B appears in the band. Therefore, the fractional band width is preferably about 17% or less, for example. In such a case, the spurious signal can be reduced by adjusting the film thickness of the piezoelectric layer 20 and the dimensions of the electrode finger 31 and the electrode finger 32.

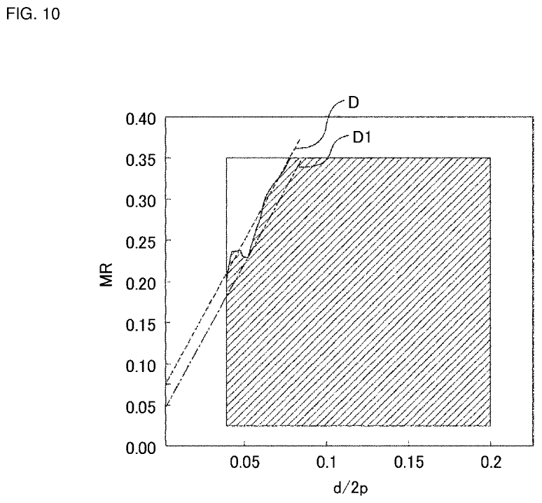

FIG. 10 is a graph for explaining the relationship between d/2p, the metallization ratio MR, and the fractional band width. In the acoustic wave device 10 of the first example embodiment, various acoustic wave devices 10 having different values of d/2p and MR were configured, and the fractional band width was measured. A hatched portion on the right side of a broken line D in FIG. 10 is a region where the fractional band width is 17% or less. The boundary between the hatched region and an unhatched region is represented by MR=about 3.5 (d/2p)+0.075, for example. That is, MR=about 1.75 (d/p)+0.075, for example. Therefore, it is preferable that MR≤about 1.75 (d/p)+0.075, for example. In such a case, it is easy to make the fractional band width about 17% or less, for example. A region on the right side of MR=about 3.5 (d/2p)+0.05, for example, indicated by a one-dot chain line D1 in FIG. 10 is more preferable. That is, if MR≤about 1.75 (d/p)+0.05, the fractional band width can be surely made about 17% or less, for example.

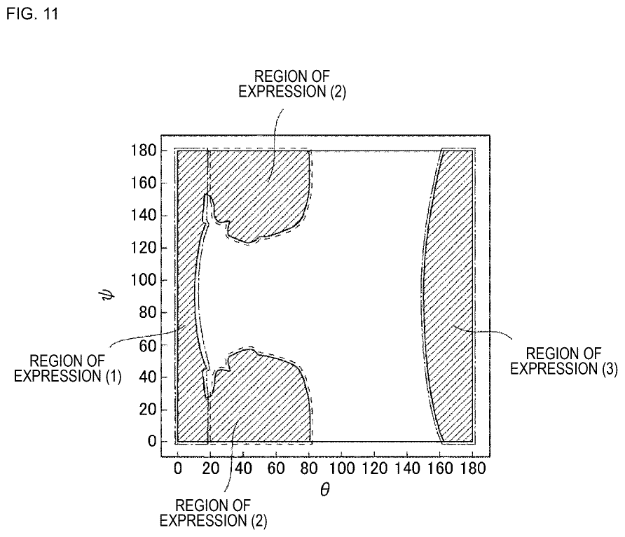

FIG. 11 is a graph for explaining a map of the fractional band width for the Euler angles (0°, θ, ψ) of lithium niobate when d/p is brought as close to zero as possible. Hatched portions in FIG. 11 are regions where a fractional band width of at least 5% or more can be obtained. When the regions are approximated, the range of such regions are expressed by the following Expressions (1), (2), and (3).

(0°±10°, 0° to 20°, any ψ) . . . (1)

(0°±10°, 20° to 80°, 0° to 60° (1−(θ−50)²/900)^{1/2}) or (0°±10°, 20° to 80°, [180°-60° (1−(θ−50)²/900)^{1/2}] to 180°) . . . (2)

(0°±10°, [180°-30° (1−(ψ−90)²/8100)^{1/2}] to 180°, any ψ) . . . (3)

Therefore, in the case of the range of Euler angles of the above Expressions (1), (2), and (3), the fractional band width is sufficiently widened, which is preferable.

Next, the detailed configuration of the load film 50 will be described. FIG. 12 is an enlarged cross-sectional view of a region A shown in FIG. 2. The load film 50 (the first extending portion 51) which overlaps with the reflector 70 disposed on one side of the arrangement direction of the plurality of electrode fingers 31 and 32 will be described with reference to FIG. 12. However, on a side opposite to the reflector 70, the second extending portion 52 (see FIGS. 1 and 2) which overlaps with the reflector 71 disposed on the other side of the arrangement direction of the plurality of electrode fingers 31 and 32 is in a linearly symmetrical relationship with respect to the first extending portion 51. The description of the first extending portion 51 can be applied to the second extending portion 52. In the following description, the first extending portion 51 and the second extending portion 52 will be simply referred to as the load film 50 when it is not necessary to distinguish them from each other.

As shown in FIG. 12, the load film 50 is provided on the first protective film 41, and overlaps with a portion of the reflector 70. In the present example embodiment, the load film 50 is provided in a region not overlapping with the IDT electrode 30 (the plurality of electrode fingers 31 and 32). That is, the load film 50 is disposed outside the IDT electrode 30 in the arrangement direction of the electrode fingers 31 and 32. The upper surface of the first protective film 41 is flat. Specifically, the upper surface of the first protective film 41 is formed substantially flat over regions where the electrode fingers 31 and 32 and the reflector 70 are provided and regions where the electrode fingers 31 and 32 and the reflector 70 are not provided.

The load film 50 is provided protruding from the upper surface of the first protective film 41. In the region overlapping with the reflector 70, a step is provided between the load film 50 and the first protective film 41. More specifically, on the first main surface 20a of the piezoelectric layer 20, there are a region in which the reflector 70 and the first protective film 41 are laminated in this order, a region in which the reflector 70, the first protective film 41, and the load film 50 are laminated in this order, and a region in which the first protective film 41 and the load film 50 are laminated in this order. In the region overlapping with the reflector 70, the step is provided between a portion where the first protective film 41 is provided but the load film 50 is not provided and a portion where the load film 50 and the first protective film 41 are laminated.

The load film 50 is provided at a position deviated from the reflector 70 outward in the arrangement direction of the plurality of electrode fingers 31 and 32. One side surface of the load film 50 is disposed to overlap with the midpoint of the reflector 70 in the width direction, and the other side surface of the load film 50 is located outside the reflector 70 in the arrangement direction. That is, the load film 50 includes an overlapping region overlapping with the reflector 70 and a non-overlapping region not overlapping with the reflector 70. The width W1 of the load film 50 is, for example, about 1.2 μm. The width W1a of the overlapping region of the load film 50 is, for example, about 0.6 μm. The width W1b of the non-overlapping region of the load film 50 is, for example, about 0.6 μm.

As described above, in the IDT electrode 30, the electrode-to-electrode pitch of the electrode fingers 31 and 32 is about 2.38 μm, and the electrode width of each of the electrode fingers 31 and 32 is about 0.6 μm, for example. The electrode-to-electrode pitch between the electrode finger 31 located outermost in the arrangement direction and the reflector 70 is about 2.38 μm, for example. The electrode width of the reflector 70 is about 1.2 μm, for example. That is, the electrode width of the reflector 70 is larger than the electrode width of each of the electrode fingers 31 and 32 of the IDT electrode 30. The reflector 70 and the electrode fingers 31 and 32 of the IDT electrode 30 are arranged with the same electrode-to-electrode pitch.

In the present example embodiment, the film thickness t4 of the load film 50 is about 55 nm, for example. As described above, the film thickness t1 of the first protective film 41 and the film thickness t2 of the second protective film 42 are about 142 nm, and the film thickness t3 of the IDT electrode 30 and the film thickness t5 of the reflector 70 are about 112 nm, for example. The film thickness t1 of the first protective film 41 is larger than the film thickness t4 of the load film 50 and larger than the film thickness t3 of the IDT electrode 30 and the film thickness t5 of the reflector 70.

The load film 50 includes the same material as the first protective film 41. In the present example embodiment, the load film 50 and the first protective film 41 include silicon oxide. Note that, even when the load film 50 and the first protective film 41 include the same material, the density of the load film 50 may be different from the density of the first protective film 41. For example, when the load film 50 is formed by vapor deposition, the actual density of the load film 50 is smaller than the density of the first protective film 41.

As described above, since the load film 50 is provided so as to overlap with the reflector 70, a region where the load film 50 and the first protective film 41 are laminated in the region overlapping with the reflector 70 has an acoustic impedance different from a region where the load film 50 is not provided and only the first protective film 41 is laminated. As a result, an acoustic reflection surface R is provided in a step portion between the load film 50 and the first protective film 41 (i.e., a portion overlapping with a side surface of the load film 50).

Thus, since the acoustic wave excited by the piezoelectric layer 20 is reflected by the acoustic reflection surface R, the acoustic wave device 10 can reduce or prevent leakage of acoustic waves in the arrangement direction of the plurality of electrode fingers 31 and 32.

FIG. 13 is a graph for explaining one example of admittance characteristics of the acoustic wave device according to the first example embodiment. More specifically, FIG. 13 is a graph for explaining a real portion of admittance, that is, a conductance component, of the acoustic wave device according to the first example embodiment. The admittance characteristics indicated in FIG. 13 show simulation results of admittance characteristics of the acoustic wave device 10 according to the first example embodiment. FIG. 13 also shows simulation results of admittance characteristics of an acoustic wave device according to a comparative example. The comparative example is an acoustic wave device having no load film 50 with respect to the first example embodiment.

As shown in FIG. 13, in the acoustic wave device according to the comparative example, ripples occur in frequency regions different from the resonant frequency. In particular, in the comparative example, large ripples indicated by dotted lines E1 and E2 occur. In contrast, in the acoustic wave device 10 according to the first example embodiment, by providing the load film 50, ripples indicated by the dotted lines E1 and E2 are reduced or prevented as compared with the comparative example. It is understood that, compared with the acoustic wave device according to the comparative example, the acoustic wave device 10 according to the first example embodiment reduces or prevents propagation loss in a frequency range indicated by the dotted line E2 on a side higher than the resonant frequency, and reduces or prevents leakage of acoustic waves.

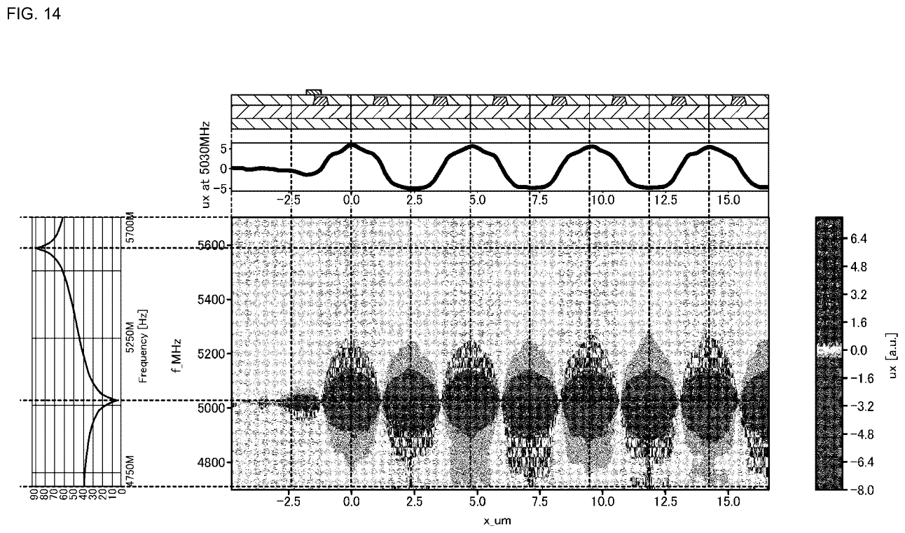

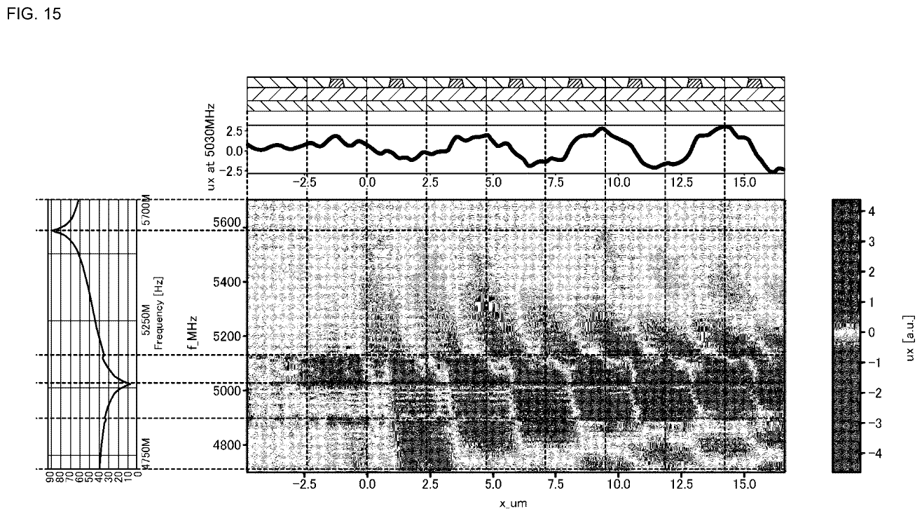

FIG. 14 is a graph for explaining the distribution of vibration modes of the acoustic wave device according to the first example embodiment. FIG. 15 is a graph for explaining the distribution of vibration modes of the acoustic wave device according to a comparative example. FIGS. 14 and 15 are graphs showing the distribution of the magnitude of the displacement of the piezoelectric layer 20 in the first example embodiment and the comparative example, in which the horizontal axis represents the X direction (the arrangement direction of the electrode fingers 31 and 32) and the vertical axis represents the frequency. The upper portions of FIGS. 14 and 15 schematically show cross-sectional views of the acoustic wave device corresponding to the X direction in the first example embodiment and the comparative example, respectively, and the left portions of FIGS. 14 and 15 show impedance characteristics of the acoustic wave device.

As shown in FIG. 15, in the acoustic wave device according to the comparative example, the dependence of displacement in the X direction (the positions of antinode and node of displacement in the X direction) exhibits large frequency dependence. For example, the position of the peak of displacement in the X direction is shifted depending on the frequency, and is not stably excited between the electrodes. Further, when focusing on a predetermined X position (in the vicinity of X=5.0 μm), the phase is inverted at the resonant frequency of 5030 MHz and at the frequencies 4900 MHz and 5120 MHz where ripples occur. As described above, in the acoustic wave device according to the comparative example, there are cases where an ideal excitation mode is not obtained.

In contrast, as shown in FIG. 14, in the acoustic wave device 10 according to the first example embodiment, the dependence of displacement in the X direction (positions of the antinode and the node of displacement in the X direction) exhibits no frequency dependence. That is, the position in the X direction showing the peak of the displacement is constant regardless of the frequency, which indicates that the excitation is stably performed between the electrodes. In addition, the magnitude of the displacement (amplitude) is also constant for each region between the electrodes, and the phase inversion in the resonant frequency and the frequency array where ripples occur does not occur. As described above, it is shown that a better excitation mode than in the comparative example can be obtained simply by providing the load film 50 in the position overlapping with the reflectors 70 and 71 located at the outermost position in the arrangement direction.

Note that the shapes, widths, film thicknesses, and the like of the load film 50, the first protective film 41, the IDT electrode 30, and the reflectors 70 and 71 described above are merely examples and may be changed as appropriate. For example, the side surface of the load film 50 may be formed in a tapered shape. The first extending portion 51 and the second extending portion 52 of the load film 50 shown in FIG. 1 may have the same width and the same film thickness. Alternatively, the first extending portion 51 and the second extending portion 52 of the load film 50 may have different widths and different film thicknesses due to variations in the manufacturing process, for example.

An example in which the load film 50 includes the same material as the first protective film 41, such as silicon oxide, for example, has been described. However, the present invention is not limited to such an example, but may include a configuration in which the load film 50 includes a material different from the first protective film 41. For example, the load film 50 may include a material having a higher density than the silicon oxide used for the first protective film 41, for example, tantalum oxide. Note that the term “density” in the present example embodiment represents a physical property value inherent to the material unless otherwise specified.

Alternatively, the load film 50 may include a material having a lower density than the silicon oxide used for the first protective film 41, for example, carbon-added silicon oxide. Alternatively, the load film 50 may include a material having a harder hardness than the silicon oxide used for the first protective film 41, for example, silicon nitride. Note that the term “hardness” in the present example embodiment represents a physical property value inherent to the material unless otherwise specified.

The material of the load film 50 described above is merely an example, and may be changed as appropriate. The load film 50 includes at least one of carbon-added silicon oxide, silicon oxide, silicon nitride, tantalum oxide, aluminum nitride, aluminum oxide, hafnium oxide, niobium oxide, or tungsten oxide. The load film 50 is not limited to a single-layer film, but may be a multilayer film. The load film 50 may include two or more of the above materials.

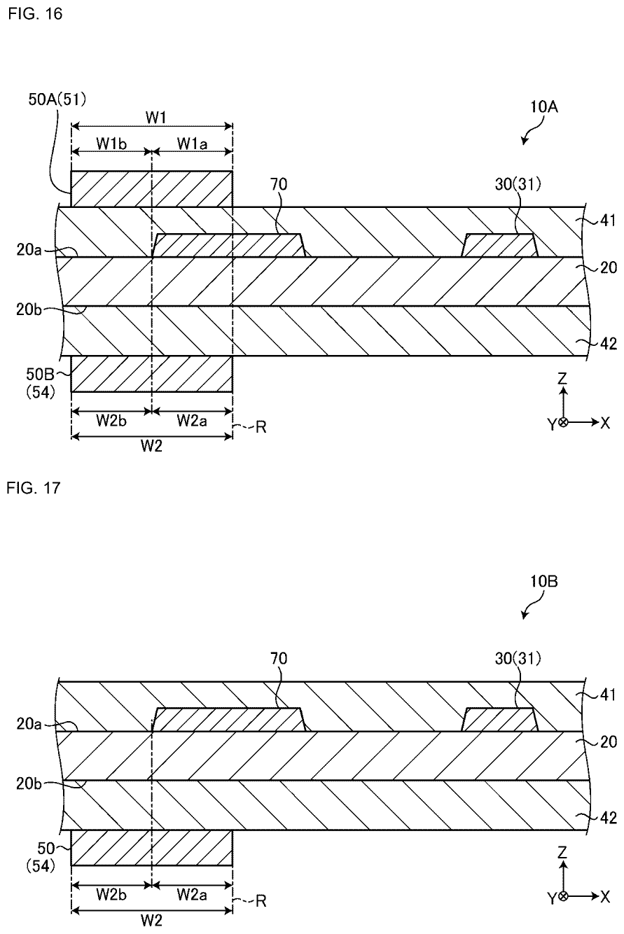

FIG. 16 is a cross-sectional view showing an acoustic wave device according to a first modification of the first example embodiment. As shown in FIG. 16, in an acoustic wave device 10A according to the first modification, the load film 50 is provided on the first protective film 41 and on a lower surface of the second protective film 42. The lower surface of the second protective film 42 is a surface of the second protective film 42 facing the support substrate 11 (see FIG. 2). In the following description, the load film 50 provided on the first protective film 41 is referred to as an upper load film 50A, and the load film 50 provided on the lower surface of the second protective film 42 is referred to as a lower load film 50B. Note that when it is not necessary to distinguish the upper load film 50A and the lower load film 50B, they are simply referred to as the load film 50.

In the present example embodiment, the upper load film 50A and the lower load film 50B include the same material, for example, silicon oxide. The first extending portion 51 of the upper load film 50A and a lower first extending portion 54 of the lower load film 50B are each provided so as to overlap with a portion of the reflector 70.

The width W1 of the upper load film 50A (the first extending portion 51) and the width W2 of the lower load film 50B (the lower first extending portion 54) are each about 1.2 μm, for example, as in the first example embodiment described above. The width W1a of the overlapping region of the upper load film 50A and the width W2a of the overlapping region of the lower load film 50B are each, for example, about 0.6 μm. The width W1b of the non-overlapping region of the upper load film 50A and the width W2b of the non-overlapping region of the lower load film 50B are each, for example, about 0.6 μm.

An example in which the upper load film 50A and the lower load film 50B formed of the same material and having the same shape has been described. However, the present invention is not limited to such an example. The upper load film 50A and the lower load film 50B may include different materials and have different shapes.

For example, the width W1 of the upper load film 50A may be different from the width W2 of the lower load film 50B. The width W2 of the lower load film 50B may be longer than the width W1 of the upper load film 50A. Alternatively, the width W2 of the lower load film 50B may be shorter than the width W1 of the upper load film 50A.

Further, the film thickness of the upper load film 50A may be different from the film thickness of the lower load film 50B. For example, the film thickness of the upper load film 50A may be smaller than the film thickness of the lower load film 50B. Alternatively, the film thickness of the upper load film 50A may be larger than the film thickness of the lower load film 50B.

Further, the material of the upper load film 50A may be different from the material of the lower load film 50B. For example, the material of the upper load film 50A may be silicon oxide, and the material of the lower load film 50B may be carbon-added silicon oxide. The material of the upper load film 50A and the material of the lower load film 50B may be formed by suitably combining the materials described above.

FIG. 17 is a cross-sectional view showing an acoustic wave device according to a second modification of the first example embodiment. In the first example embodiment described above, a configuration in which the load film 50 is provided on the first main surface 20a side of the piezoelectric layer 20 and on the first protective film 41 has been described, but the present invention is not limited to such a configuration. As shown in FIG. 17, in an acoustic wave device 10B according to the second modification, the load film 50 (the lower first extending portion 54) is provided on the second main surface 20b side of the piezoelectric layer 20 and on the lower surface of the second protective film 42. In other words, the load film 50 is not provided on the first main surface 20a side of the piezoelectric layer 20, and the upper surface of the first protective film 41 is flat.

The lower surface of the second protective film 42 is flat along the second main surface 20b of the piezoelectric layer 20. The load film 50 is provided on the lower surface of the second protective film 42 and overlaps with a portion of the reflector 70. The load film 50 is provided protruding from the lower surface of the second protective film 42. In the present example embodiment, the second main surface 20b of the piezoelectric layer 20 has, in the region overlapping with the reflector 70, a region where the second protective film 42 is provided but the load film 50 is not provided, and a region where the second protective film 42 and the load film 50 are laminated. As a result, in the region overlapping with the reflector 70, a step is provided between the load film 50 and the second protective film 42.

In the second modification, the load film 50 includes the same material as the first protective film 41 and the second protective film 42, for example, silicon oxide. The width W2 of the load film 50 is, for example, about 1.2 μm. The width W2a of the overlapping region of the load film 50 is, for example, about 0.6 μm. The width W2b of the non-overlapping region of the load film 50 is, for example, about 0.6 μm.

The configuration of the lower first extending portion 54 in plan view is the same as that of the first extending portion 51 (see FIG. 1), and repeated description thereof is omitted. Further, although not shown, a lower second extending portion is also provided on the opposite side of the lower first extending portion 54 in the arrangement direction of the plurality of electrode fingers 31 and 32, at a position overlapping with the reflector 71 (see FIG. 1).

In the second modification, since the load film 50 is not provided on the first protective film 41 as compared with the first example embodiment and the first modification, the resonant frequency can be easily adjusted by changing the film thickness of the first protective film 41.

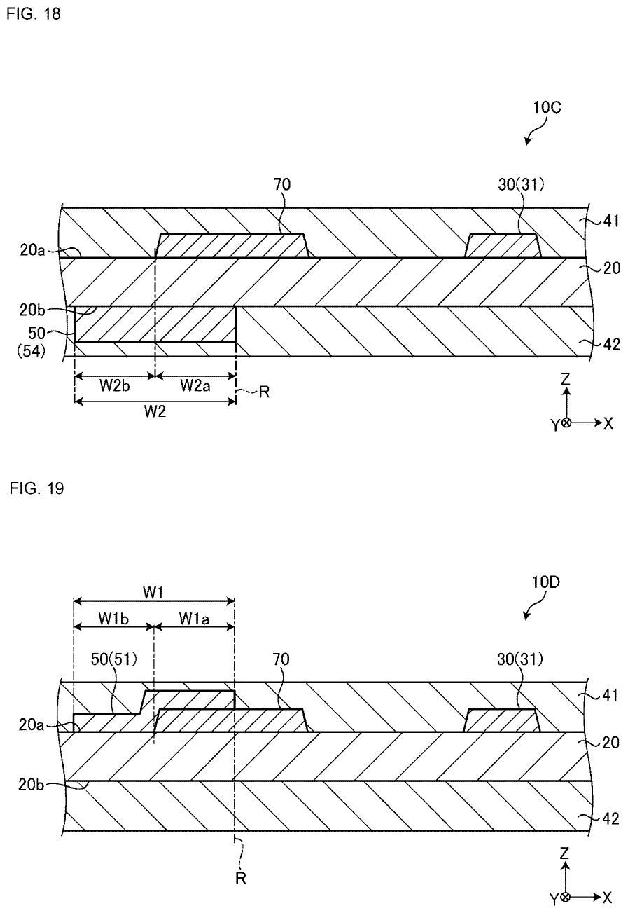

FIG. 18 is a cross-sectional view showing an acoustic wave device according to a third modification of the first example embodiment. In the first example embodiment, the first modification, and the second modification described above, a configuration in which the load film 50 is provided on at least one of the first protective film 41 and the lower surface of the second protective film 42 has been described, but the present invention is not limited to such a configuration.

As shown in FIG. 18, in an acoustic wave device 10C according to the third modification, the load film 50 is provided on the second main surface 20b of the piezoelectric layer 20. The second protective film 42 is provided on the second main surface 20b of the piezoelectric layer 20 to cover the load film 50. The lower surface of the second protective film 42 is provided flat over regions overlapping with the load film 50 and regions not overlapping with the load film 50. Further, in the present modification, the load film 50 is not provided on the first main surface 20a side of the piezoelectric layer 20, and the upper surface of the first protective film 41 is flat.

The load film 50 is provided so as to overlap a portion of the reflector 70. In the third modification, the load film 50 includes a material different from that of the first protective film 41 and the second protective film 42, such as tantalum oxide. However, the present invention is not limited to such a configuration. The load film 50 may alternatively be formed of one of the materials described above, such as carbon-added silicon oxide and silicon nitride.

FIG. 19 is a cross-sectional view showing an acoustic wave device according to a fourth modification of the first example embodiment. As shown in FIG. 19, in an acoustic wave device 10D according to the fourth modification, the load film 50 is provided on the reflector 70. More specifically, the load film 50 is provided over an upper surface of the reflector 70, a side surface of the reflector 70, and a portion of the first main surface 20a of the piezoelectric layer 20 where the reflector 70 is not provided. The load film 50 is provided to follow the shape of the step provided between the piezoelectric layer 20 and the reflector 70.

The load film 50 includes tantalum oxide. However, the load film 50 does not have to be formed of tantalum oxide, but may alternatively be formed of one of the materials described above, such as carbon-added silicon oxide and silicon nitride. The widths W1, W1a, and W1b of the load film 50 are formed with the same dimensions as those of the first example embodiment described above. The film thickness of the load film 50 is smaller than that of the first example embodiment described above. The sum of the film thickness of the load film 50 and the film thickness of the reflector 70 is smaller than the film thickness of the first protective film 41.

The first protective film 41 is provided on the first main surface 20a of the piezoelectric layer 20 to cover the load film 50, the reflector 70, and the IDT electrode 30. That is, the first protective film 41 has, in the region overlapping with the reflector 70, a portion where the load film 50 and the first protective film 41 are laminated in this order and a portion where the first protective film 41 is provided but the load film 50 is not provided. The upper surface of the first protective film 41 is flat over regions where the first protective film 41 overlaps with the load film 50, the reflector 70, and the IDT electrode 30 and regions where the load film 50, the reflector 70, and the IDT electrode 30 are not provided.

In the fourth modification, an example in which the upper surface of the load film 50 and the upper surface of the reflector 70 are covered by the first protective film 41 has been described, but the present invention is not limited to such an example. For example, the upper surface of the load film 50 may be provided in the same plane as the upper surface of the first protective film 41. In such a case, in the region overlapping with the reflector 70, the film thickness of the load film 50 and the film thickness of the first protective film 41 are equal.

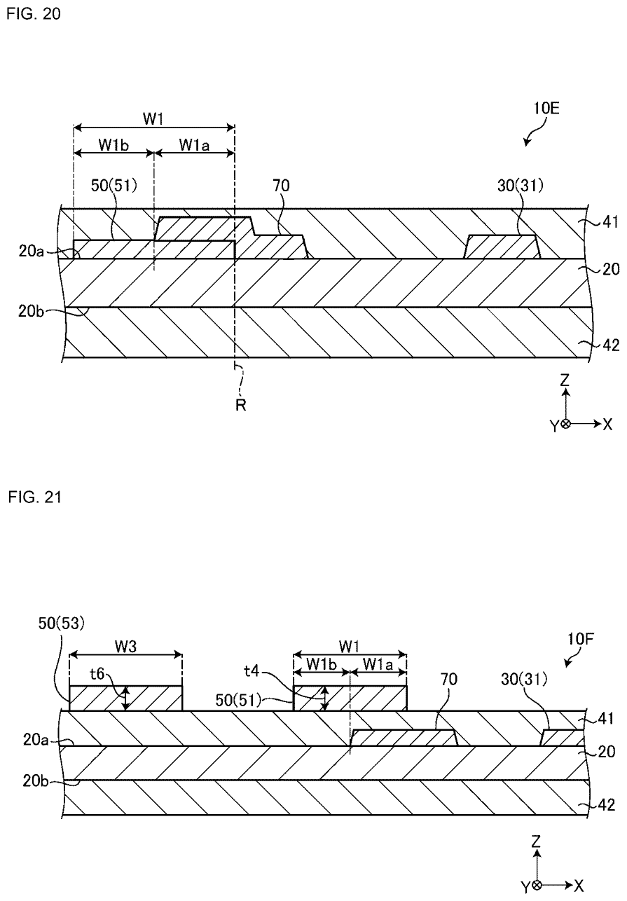

FIG. 20 is a cross-sectional view showing an acoustic wave device according to a fifth modification of the first example embodiment. As shown in FIG. 20, in an acoustic wave device 10E according to the fifth modification, the load film 50 is provided on the first main surface 20a of the piezoelectric layer 20. The reflector 70 covers a portion of the load film 50, and is provided on the first main surface 20a of the piezoelectric layer 20. That is, the load film 50 is provided between the first main surface 20a of the piezoelectric layer 20 and the reflector 70 in a direction perpendicular to the first main surface 20a of the piezoelectric layer 20.

The first protective film 41 is provided on the first main surface 20a of the piezoelectric layer 20 to cover the load film 50, the reflector 70, and the IDT electrode 30. That is, in the present example embodiment, on the first main surface 20a of the piezoelectric layer 20, there are a region in which the reflector 70 and the first protective film 41 are laminated in this order, a region in which the load film 50, the reflector 70, and the first protective film 41 are laminated in this order, and a region in which the load film 50 and the first protective film 41 are laminated in this order. The upper surface of the first protective film 41 is flat over regions where the first protective film 41 overlaps with the load film 50, the reflector 70, and the IDT electrode 30 and regions where the load film 50, the reflector 70, and the IDT electrode 30 are not provided.

The load film 50 includes silicon oxide. However, the present invention is not limited to such a configuration. The load film 50 may alternatively include one of the materials described above, such as tantalum oxide, carbon-added silicon oxide, and silicon nitride. Also, in the present modification, the sum of the film thickness of the load film 50 and the film thickness of the reflector 70 is smaller than the film thickness of the first protective film 41.

FIG. 21 is a cross-sectional view showing an acoustic wave device according to a sixth modification of the first example embodiment. As shown in FIG. 21, in an acoustic wave device 10F according to the sixth modification of the first example embodiment, the load film 50 has the first extending portion 51 overlapping with the reflector 70, and an outer load film 53 provided in a region outside the first extending portion 51 in the arrangement direction and not overlapping with the reflector 70 and the IDT electrode 30 (the electrode fingers 31 and 32).

The outer load film 53 is provided on the first protective film 41 on the same layer as the first extending portion 51, and is provided separately from the first extending portion 51. The outer load film 53 includes silicon oxide, which is the same as that of the first extending portion 51. The film thickness t6 of the outer load film 53 is the same as the film thickness t4 of the first extending portion 51. The width W3 of the outer load film 53 is the same as the width W1 of the first extending portion 51. However, the shape (the film thickness t5 and the width W3) of the outer load film 53 may be different from the shape (the film thickness t4 and the width W1) of the first extending portion 51.

The sixth modification can be combined with each of the first to fifth modifications described above. That is, the first extending portion 51 and the outer load film 53 may be provided on both the first protective film 41 and the lower surface of the second protective film 42, or may be provided not on the first protective film 41 but on the lower surface of the second protective film 42. Alternatively, the first extending portion 51 and the outer load film 53 may be provided on the first main surface 20a or the second main surface 20b of the piezoelectric layer 20.

In the first to sixth modifications, simulation results of admittance characteristics are omitted. In any of the first to sixth modifications, the load film 50 is provided in the region overlapping with the reflectors 70 and 71. Therefore, in the first to sixth modifications, as in the acoustic wave device 10 according to the first example embodiment, at least one of the ripples indicated by the dotted lines E1 and E2 or the dotted line E3 (see FIG. 13) is reduced or prevented as compared with the comparative example. In addition, in any of the first to sixth modifications, propagation loss is reduced or prevented as compared with the comparative example.

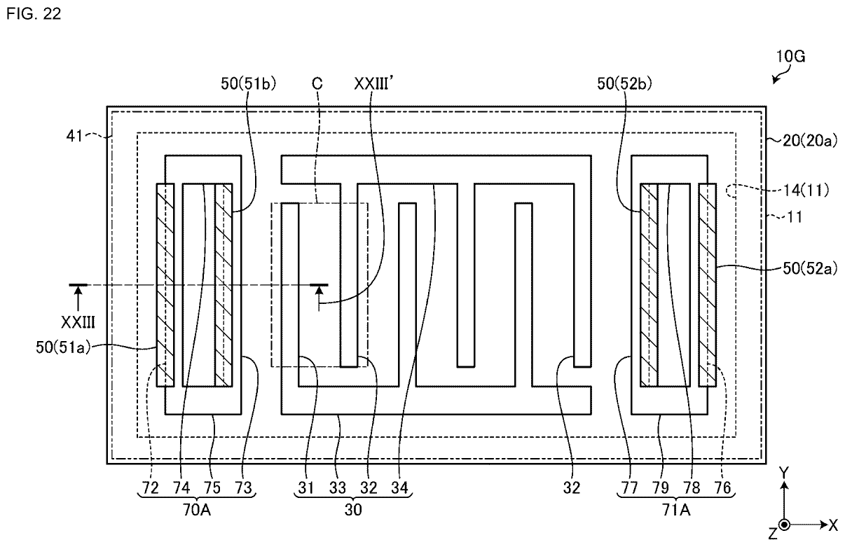

FIG. 22 is a plan view showing an acoustic wave device according to a second example embodiment of the present invention. As shown in FIG. 22, in an acoustic wave device 10G according to the second example embodiment, a reflector 70A has a plurality of reflective electrode fingers 72 and 73 and a plurality of reflective busbar electrodes 74 and 75. The plurality of reflective electrode fingers 72 and 73 are disposed adjacent to each other in the X direction with an interval. The reflective busbar electrodes 74 and 75 extend in the X direction, and are disposed separately from each other in the Y direction.

More specifically, the plurality of reflective electrode fingers 72 and 73 are arranged in the arrangement direction of the plurality of electrode fingers 31 and 32 of the IDT electrode 30, and extend along the extending direction of the electrode fingers 31 and 32. One end side of the plurality of reflective electrode fingers 72 and 73 in the extending direction is connected to the reflective busbar electrode 74. The other end side of the plurality of reflective electrode fingers 72 and 73 in the extending direction is connected to the reflective busbar electrode 75.

A reflector 71A includes a plurality of reflective electrode fingers 76 and 77 and a plurality of reflective busbar electrodes 78 and 79. The configuration of the reflector 71A is the same as that of the reflector 70A, and repeated description thereof is omitted.

The second example embodiment shows an example in which the reflector 70A includes two reflective electrode fingers 72 and 73, and the reflector 71A includes two reflective electrode fingers 76 and 77. However, the present invention is not limited to such an example. The reflectors 70A and 71A may each include three or more reflective electrode fingers.

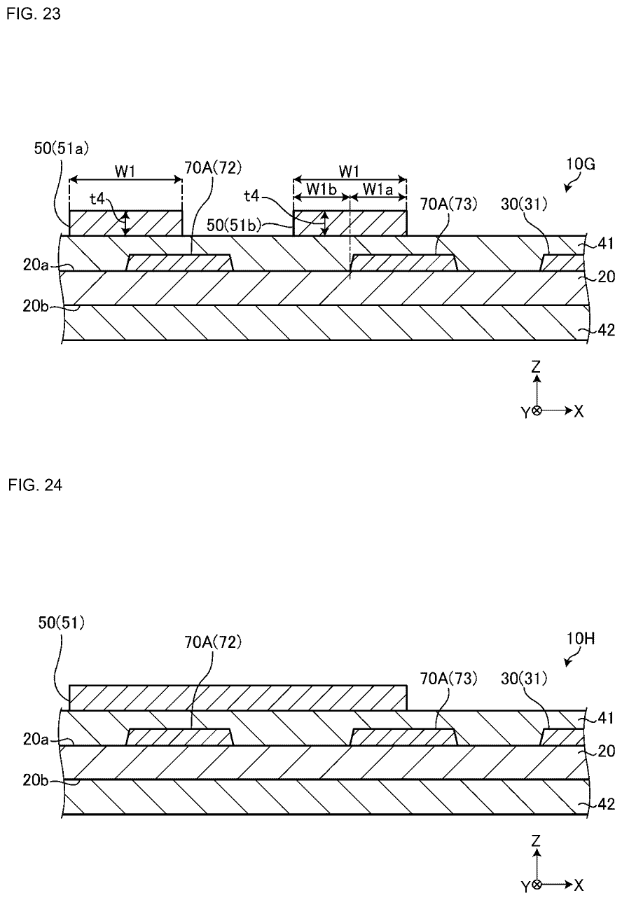

FIG. 23 is a cross-sectional view taken along line XXIII-XXIII′ of FIG. 22. The load film 50 (first extending portions 51a and 51b) provided in a region overlapping with the reflector 70A will be described with reference to FIG. 23. However, the load film 50 (second extending portions 52a and 52b) provided in a region overlapping with the reflector 71A on the side opposite to the reflector 70A is in a linearly symmetrical relationship with respect to the first extending portions 51a and 51b. The description of the first extending portions 51a and 51b can be applied to the second extending portions 52a and 52b.

As shown in FIG. 23, a plurality of load films 50 are provided for the plurality of reflective electrode fingers 72 and 73, respectively. More specifically, the plurality of load films 50 include two first extending portions 51a and 51b. The first extending portions 51a and 51b of the plurality of load films 50 are provided on the first protective film 41. The first extending portion 51a is provided in a region overlapping with the reflective electrode finger 72 located outermost in the arrangement direction, and extends along the extending direction of the reflective electrode finger 72. The first extending portion 51b is provided in a region overlapping with the reflective electrode finger 73 adjacent to the reflective electrode finger 72, and extends along the extending direction of the reflective electrode finger 73. The load film 50 (the first extending portion 51a) overlapping the reflective electrode finger 72 and the load film 50 (the first extending portion 51b) overlapping the reflective electrode finger 73 are disposed separately from each other.

In the second example embodiment, the materials and shapes of the first extending portions 51a and 51b of the plurality of load films 50 are the same as those of the load film 50 of the first example embodiment. That is, the load film 50 includes silicon oxide as in the first example embodiment. The film thickness t4 of the first extending portions 51a and 51b of the load film 50 is about 55 nm, for example. The width W1 of the first extending portions 51a and 51b of the load film 50 is, for example, about 1.2 μm. The width W1a of the overlapping region of the first extending portions 51a and 51b of the load film 50 is, for example, about 0.6 μm. The width W1b of the non-overlapping region of the first extending portions 51a and 51b of the load film 50 is, for example, about 0.6 μm.

The widths W1, W1a, and W1b of the first extending portions 51a and 51b are merely examples, and can be changed as appropriate. The width W1 and the film thickness t4 of the first extending portion 51a of the load film 50 may be different from the width W1 and the film thickness t4 of the first extending portion 51b. The material of the load film 50 is not limited to silicon oxide, and the first extending portions 51a and 51b of the load film 50 include at least one of carbon-added silicon oxide, silicon oxide, silicon nitride, tantalum oxide, aluminum nitride, aluminum oxide, hafnium oxide, niobium oxide and tungsten oxide.

FIG. 24 is a cross-sectional view showing an acoustic wave device according to a seventh modification of the second example embodiment. As shown in FIG. 24, in an acoustic wave device 10H according to the seventh modification, the load film 50 is provided in a region overlapping with the reflective electrode finger 72 of the reflector 70A and the reflective electrode finger 73 of the reflector 70A adjacent to the reflective electrode finger 72.

The load film 50 is provided continuously over the two reflective electrode fingers 72 and 73. One side surface of the load film 50 is disposed to overlap with a midpoint of the reflective electrode finger 73 in the width direction, and the other side surface of the load film 50 is located outside the reflective electrode finger 72 in the arrangement direction.

The load film 50 includes silicon oxide as in the second example embodiment. However, the load film 50 does not have to be formed of silicon oxide, but may alternatively be formed of at least one of carbon-added silicon oxide, silicon oxide, silicon nitride, tantalum oxide, aluminum nitride, aluminum oxide, hafnium oxide, niobium oxide, or tungsten oxide.

In the second example embodiment and the seventh modification, a configuration in which the load film 50 (the first extending portions 51, 51a, and 51b) is provided on the first protective film 41 has been described. However, the second example embodiment and the seventh modification can be combined with each of the first to sixth modifications described above. That is, the load film 50 may be provided on both the first protective film 41 and the lower surface of the second protective film 42, or may be provided not on the first protective film 41 but on the lower surface of the second protective film 42. Alternatively, the load film 50 may be provided on the first main surface 20a or the second main surface 20b of the piezoelectric layer 20. Alternatively, the load film 50 may have the outer load film 53 provided in a region outside the first extending portions 51, 51a, and 51b in the arrangement direction and not overlapping with the reflector 70A and the IDT electrode 30 (the electrode fingers 31 and 32).

In the second example embodiment and the seventh modification, simulation results of admittance characteristics are omitted. In both the second example embodiment and the seventh modification, the load film 50 is provided in the region overlapping with the reflectors 70A and 71A. Therefore, in the second example embodiment and the seventh modification, as in the acoustic wave device 10 according to the first example embodiment, at least one of ripples indicated by dotted lines E1 and E2 or dotted line E3 (see FIG. 13) is reduced or prevented as compared with the comparative example. Further, in both the second example embodiment and the seventh modification, propagation loss is reduced or prevented as compared with the comparative example.

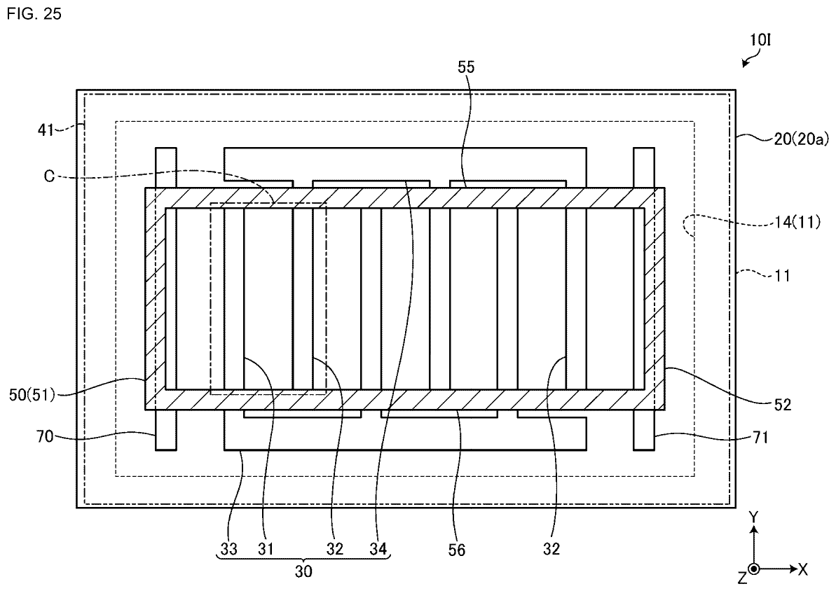

FIG. 25 is a plan view showing an acoustic wave device according to a third example embodiment of the present invention. As shown in FIG. 25, in an acoustic wave device 10I according to the third example embodiment, the load film 50 is formed in a frame shape. Specifically, the load film 50 includes a first extending portion 51, a second extending portion 52, a third extending portion 55, and a fourth extending portion 56.

The first extending portion 51 is provided in a region overlapping with the reflector 70 (first reflector) located outside the IDT electrode 30 in the arrangement direction of the plurality of electrode fingers 31 and 32, and extends along the extending direction of the reflector 70. The second extending portion 52 is provided in a region overlapping with the reflector 71 (second reflector) located outside the IDT electrode 30 in the arrangement direction of the plurality of electrode fingers 31 and 32, on a side opposite to the reflector 70, and extends along the extending direction of the reflector 71.

The third extending portion 55 is connected to one end side of the first extending portion 51 and one end side of the second extending portion 52 in the extending direction, and extends in the arrangement direction of the plurality of electrode fingers 31 and 32. The third extending portion 55 extends so as to overlap with an end portion of each of the plurality of the electrode fingers 31 in the extending direction. The fourth extending portion 56 is connected to the other end side of the first extending portion 51 and the other end side of the second extending portion 52 in the extending direction, and extends in the arrangement direction of the plurality of electrode fingers 31 and 32. The fourth extending portion 56 extends so as to overlap with an end portion of each of the plurality of the electrode fingers 32 in the extending direction.

Thus, in the acoustic wave device 10I according to the third example embodiment, the load film 50 has a continuous frame shape. As a result, the acoustic reflection surface R (see FIG. 12) is provided along each of the first extending portion 51, the second extending portion 52, the third extending portion 55, and the fourth extending portion 56. Therefore, the acoustic wave device 10I can reduce or prevent leakage of acoustic waves in the arrangement direction of the plurality of electrode fingers 31 and 32, and can reduce or prevent leakage of acoustic waves in the extending direction of the plurality of electrode fingers 31 and 32.

The third extending portion 55 and the fourth extending portion 56 are provided on the same layer as the first extending portion 51 and the second extending portion 52 shown in the first example embodiment (see FIG. 12), and include the same material and have the same film thickness as the first extending portion 51 and the second extending portion 52 shown in the first example embodiment. Thus, the third extending portion 55 and the fourth extending portion 56 can be formed in the same process as the first extending portion 51 and the second extending portion 52, so that the manufacturing cost can be reduced.

In the third example embodiment, the load film 50 is provided on the first protective film 41 as in the first example embodiment (see FIG. 12). However, the load film 50 is not limited to such a configuration. The load film 50 of the third example embodiment can be combined with each of the example embodiments and modifications described above.

A configuration in which the load film 50 has a continuous frame shape, and the first extending portion 51, the second extending portion 52, the third extending portion 55, and the fourth extending portion 56 are connected to the load film 50 has been described with reference to FIG. 25. However, the load film 50 is not limited to such a configuration, but may have a configuration in which a slit is formed in a portion of the load film 50, and at least one of the first extending portion 51, the second extending portion 52, the third extending portion 55, and the fourth extending portion 56 are provided so as to be separated from the other components. For example, at least one of the third extending portion 55 and the fourth extending portion 56 may be disposed so as to be separated from the first extending portion 51 and the second extending portion 52.

In addition, a configuration in which the first extending portion 51, the second extending portion 52, the third extending portion 55, and the fourth extending portion 56 have the same width has been described with reference to FIG. 25. However, the present invention is not limited to such a configuration, but may include a configuration in which at least one of the first extending portion 51, the second extending portion 52, the third extending portion 55, and the fourth extending portion 56 has a width (length in a direction perpendicular to the extending direction) different from the other components. For example, the width of the third extending portion 55 and the fourth extending portion 56 (the length in a direction perpendicular to the extending direction) may be larger than the width of the first extending portion 51 and the second extending portion 52 (the length in a direction perpendicular to the extending direction).

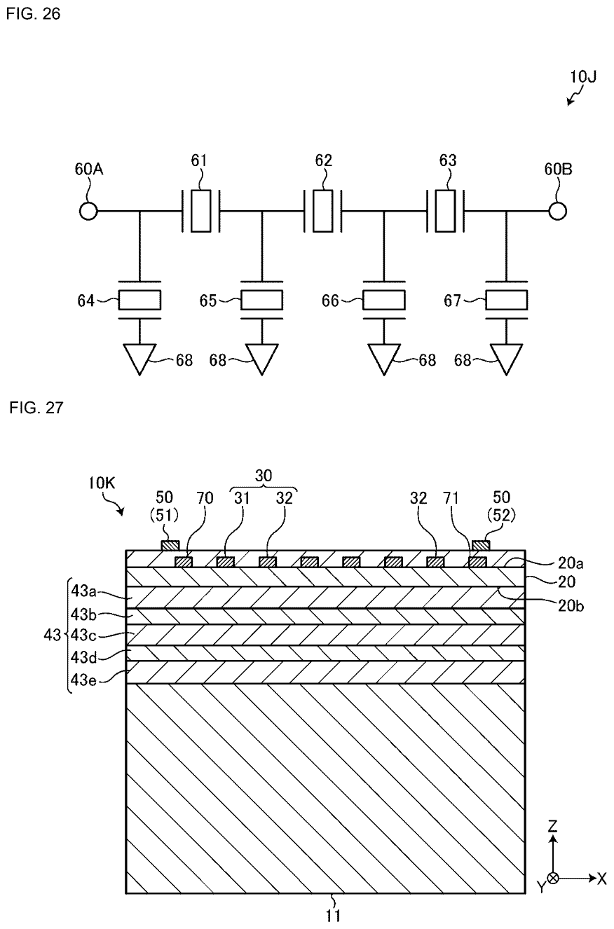

FIG. 26 is a circuit diagram showing an acoustic wave device according to a fourth example embodiment of the present invention. As shown in FIG. 26, an acoustic wave device 10J according to the fourth example embodiment includes a plurality of series arm resonators 61, 62, and 63 and a plurality of parallel arm resonators 64, 65, 66, and 67. The plurality of series arm resonators 61, 62, and 63 are connected in series to a signal path between an input terminal 60A and an output terminal 60B. The plurality of parallel arm resonators 64, 65, 66, and 67 are connected in parallel to each other between the signal path between the input terminal 60A and the output terminal 60B and a ground 68. The acoustic wave device 10J according to the fourth example embodiment is a so-called ladder filter.

One terminal of the plurality of series arm resonators 61, 62, and 63 connected in series is electrically connected to the input terminal 60A, and the other terminal is electrically connected to the output terminal 60B. One terminal of the parallel arm resonator 64 is electrically connected to the input terminal 60A, and the other terminal is electrically connected to the ground 68. One terminal of the parallel arm resonator 65 is electrically connected to a signal path connecting the series arm resonator 61 and the series arm resonator 62, and the other terminal is electrically connected to the ground 68. One terminal of the parallel arm resonator 66 is electrically connected to a signal path connecting the series arm resonator 62 and the series arm resonator 63, and the other terminal is electrically connected to the ground 68. One terminal of the parallel arm resonator 67 is electrically connected to the output terminal 60B, and the other terminal is electrically connected to the ground 68.

In the present example embodiment, the plurality of series arm resonators 61, 62, and 63 and the plurality of parallel arm resonators 64, 65, 66, and 67 use load films 50 having different configurations. For example, the plurality of series arm resonators 61, 62, and 63 each include the load film 50 shown in the first example embodiment (see FIGS. 12 and 13). The admittance characteristics of the plurality of series arm resonators 61, 62, and 63 are the same as those shown in FIG. 13, and repeated description thereof is omitted.

On the other hand, the plurality of parallel arm resonators 64, 65, 66, and 67 each have the load film 50 described in the second example embodiment, which is different from that of the first example embodiment.

In the present example embodiment, by changing the configuration of the load film 50 between the plurality of series arm resonators 61, 62, and 63 and the plurality of parallel arm resonators 64, 65, 66, and 67, a better output waveform of the filter can be obtained.

In the acoustic wave device 10J according to the fourth example embodiment, an example obtained by combining the load film 50 described in the first example embodiment with the load film 50 described in the second example embodiment has been described. However, the present invention is not limited to such an example. The fourth example embodiment can be combined with each of the example embodiments and modifications described above.

FIG. 27 is a cross-sectional view showing an acoustic wave device according to an eighth modification of an example embodiment of the present invention. In the acoustic wave device 10 of the first example embodiment, a so-called membrane structure in which the support substrate 11 has the cavity portion 14, and the cavity portion 14 (space portion) is provided on the side of the second main surface 20b of the piezoelectric layer 20 has been described. However, the present invention is not limited to such a structure.

As shown in FIG. 27, in an acoustic wave device 10K according to the eighth modification, an acoustic multilayer film 43 is laminated on the second main surface 20b of the piezoelectric layer 20. The acoustic multilayer film 43 has a laminated structure of low acoustic impedance layers 43a, 43c, and 43e having relatively low acoustic impedance and high acoustic impedance layers 43b and 43d having relatively high acoustic impedance. The low acoustic impedance layers 43a, 43c, and 43e are, for example, silicon oxide layers, and the high acoustic impedance layers 43b and 43d are, for example, metal layers such as tungsten and platinum or dielectric layers such as aluminum nitride and silicon nitride. When the acoustic multilayer film 43 is used, it is possible to confine the bulk wave in the first-order thickness-shear mode in the piezoelectric layer 20 without using the cavity portion 14.

Also in the acoustic wave device 10K, resonance characteristics based on the bulk wave in the first-order thickness-shear mode can be obtained by setting the above d/p to about 0.5 or less, for example. In the acoustic multilayer film 43, the number of laminated layers of the low acoustic impedance layers 43a, 43c, and 43e and the high acoustic impedance layers 43b and 43d is not particularly limited. It is sufficient to dispose at least one layer of the high acoustic impedance layers 43b and 43d on a side farther from the piezoelectric layer 20 than the low acoustic impedance layers 43a, 43c, and 43e.

The low acoustic impedance layers 43a, 43c, and 43e and the high acoustic impedance layers 43b and 43d may include any suitable material as long as the relationship between the acoustic impedances described above is satisfied. For example, the low acoustic impedance layers 43a, 43c, and 43e may include silicon oxide, silicon oxynitride, or the like. The high acoustic impedance layers 43b and 43d may include alumina, silicon nitride, metal, or the like.

An example in which the load film 50 according to the first example embodiment is provided has been described with reference to FIG. 27. However, the present invention is not limited to such an example. The eighth modification can be combined with each of the example embodiments and modifications described above.

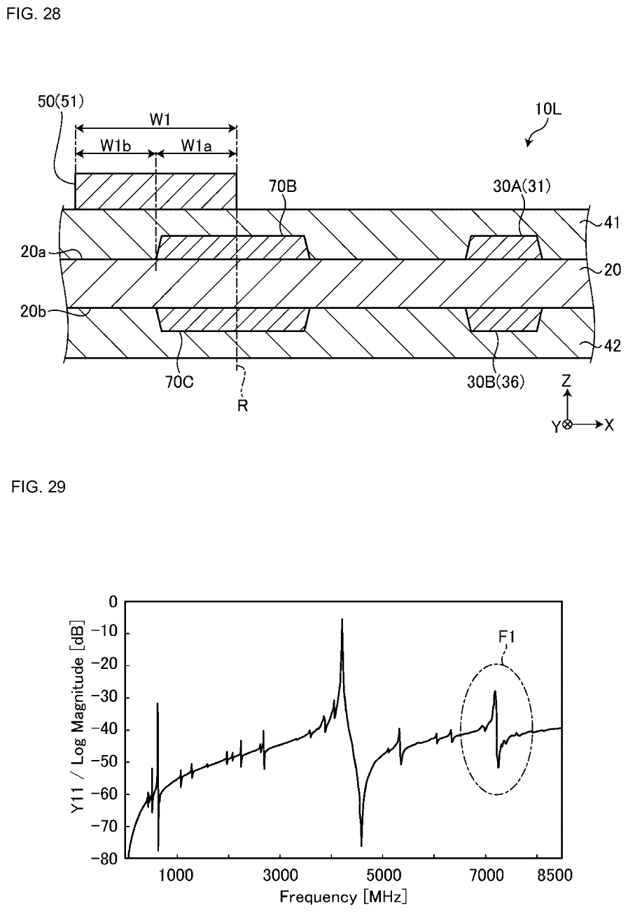

FIG. 28 is a cross-sectional view showing an acoustic wave device according to a ninth modification of an example embodiment of the present invention. In the acoustic wave device 10 according to the first example embodiment described above, a configuration in which the IDT electrode 30 is provided on the first main surface 20a of the piezoelectric layer 20 has been described. However, the present invention is not limited to such a configuration. As shown in FIG. 28, an acoustic wave device 10L according to the ninth modification includes a first IDT electrode 30A provided on the first main surface 20a of the piezoelectric layer 20 and a second IDT electrode 30B provided on the second main surface 20b of the piezoelectric layer 20. The first IDT electrode 30A and the second IDT electrode 30B have the same configuration as the IDT electrode 30 (see FIGS. 1 and 2).

A plurality of electrode fingers 36 (only one electrode finger 36 is shown in FIG. 28) of the second IDT electrode 30B are provided in regions overlapping with the plurality of electrode fingers 31 of the first IDT electrode 30A. The electrode fingers 36 of the second IDT electrode 30B have the same width as the electrode fingers 31 of the first IDT electrode 30A, and are provided with the same electrode-to-electrode pitch as the electrode fingers 31 of the first IDT electrode 30A.

The acoustic wave device 10L according to the ninth modification includes an upper reflector 70B provided on the first main surface 20a of the piezoelectric layer 20 and a lower reflector 70C provided on the second main surface 20b of the piezoelectric layer 20. The upper reflector 70B is provided on the same layer as the first IDT electrode 30A, and the lower reflector 70C is provided on the same layer as the second IDT electrode 30B. The upper reflector 70B and the lower reflector 70C have the same configuration as the reflectors 70 and 71 of the first example embodiment.

The lower reflector 70C is provided in a region overlapping with the upper reflector 70B. The load film 50 is provided on the first protective film 41, and is provided in a region overlapping with the upper reflector 70B and the lower reflector 70C.

In the ninth modification, the first IDT electrode 30A and the upper reflector 70B are provided on the first main surface 20a of the piezoelectric layer 20, and the second IDT electrode 30B and the lower reflector 70C are provided on the second main surface 20b of the piezoelectric layer 20, so that the temperature coefficients of frequency (TCF) can be improved.

An example in which the load film 50 according to the first example embodiment is provided has been described with reference to FIG. 28. However, the present invention is not limited to such an example. The ninth modification can be combined with each of the example embodiments and modifications described above.

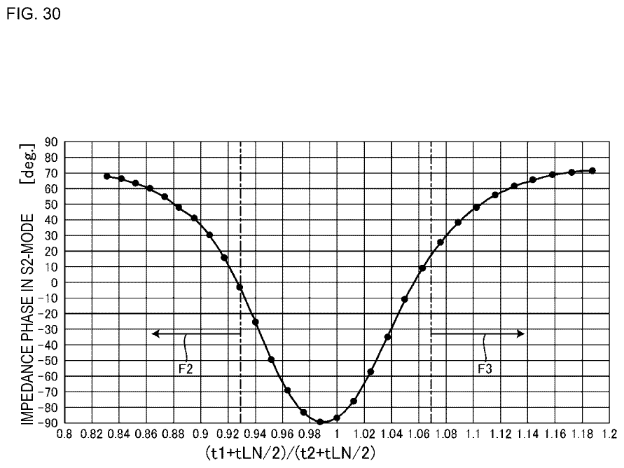

FIG. 29 is a graph for explaining one example of admittance characteristics of an acoustic wave device according to a tenth modification of an example embodiment of the present invention. FIG. 30 is a graph for explaining one example of impedance phases in a high-order mode. The acoustic wave device according to the tenth modification shown in FIG. 29 will be explained with respect to a configuration in which the film thickness of the first protective film 41 and the film thickness of the second protective film 42 are made different in the acoustic wave device 10 according to the first example embodiment described above.

FIG. 29 shows the frequency characteristics of the absolute value of the admittance of the acoustic wave device according to the tenth modification. As shown in FIG. 29, in the acoustic wave device according to the tenth modification, resonance in a high-order mode (hereinafter referred to as a S2-mode) occurs in a frequency region indicated by a one-dot chain line F1, which differs from the resonant frequency.

The horizontal axis of the graph shown in FIG. 30 indicates the ratio ((t1+tLN/2)/(t2+tLN/2)) of the sum of the film thickness t1 of the first protective film 41 and ½ of the film thickness tLN of the piezoelectric layer 20 (i.e., (t1+tLN/2)) to the sum of the film thickness t2 of the second protective film 42 and ½ of the film thickness tLN of the piezoelectric layer 20 (i.e., (t2+tLN/2)). The vertical axis of the graph shown in FIG. 30 corresponds to the intensity of the S2-mode.

In FIG. 30, the ranges indicated by arrows F2 and F3 indicate the ratio (t1+tLN/2)/(t2+tLN/2) in the configuration of the acoustic resonance device disclosed in Japanese Unexamined Patent Application Publication No. 2022-524136. In the acoustic resonance device disclosed in Japanese Unexamined Patent Application Publication No. 2022-524136, the ratio (t1+tLN/2)/(t2+tLN/2) is 0.93 or less and 1.07 or more, and the intensity of the S2-mode is high.

On the other hand, in the tenth modification, the ratio (t1+tLN/2)/(t2+tLN/2) is about 0.94 or more and about 1.06 or less, for example, and the intensity of the S2-mode is lower than that in the acoustic resonance device disclosed in Japanese Unexamined Patent Application Publication No. 2022-524136. In other words, in the tenth modification, when A represents the sum of the distances from the center of the film thickness of the piezoelectric layer 20 to the top surface of the first protective film 41, and B represents the sum of the distances from the center of the film thickness of the piezoelectric layer 20 to the top surface of the second protective film 42, the value of A/B is preferably about 1−0.06 or more and about 1+0.06 or less, for example.

In the tenth modification, a case where the film thickness of the first protective film 41 and the film thickness of the second protective film 42 are made different in the acoustic wave device 10 according to the first example embodiment has been described. However, the present invention is not limited to such a case. The relationship between the film thickness t1 of the first protective film 41, the film thickness tLN of the piezoelectric layer 20, and the film thickness t2 of the second protective film 42 in the tenth modification can be combined with each of the example embodiments and modifications described above.

Note that the example embodiments described above are intended to facilitate understanding of the present invention, and are not intended to limit the interpretation of the present invention. The present invention may be modified or improved without departing from the spirit thereof, and the present invention includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface facing the first main surface in a first direction;
an IDT electrode that is provided on at least one of the first main surface and the second main surface of the piezoelectric layer, and that includes a plurality of electrode fingers arranged in an arrangement direction;
a reflector adjacent to the IDT electrode in the predetermined;
a support that faces the second main surface of the piezoelectric layer, and that includes an acoustic reflection portion on a side of the second main surface of the piezoelectric layer; and
a load film provided in a region overlapping with the reflector in a plan view from the first direction; wherein
when a thickness of the piezoelectric layer is d and a distance between centers of the adjacent electrode fingers is p, d/p is about 0.5 or less.

2. The acoustic wave device according to claim 1, further comprising a protective film provided on at least one of the first main surface or the second main surface of the piezoelectric layer.

3. The acoustic wave device according to claim 2, wherein
the protective film includes a first protective film provided on the first main surface of the piezoelectric layer to cover the IDT electrode and the reflector; and
the load film is provided on the first protective film.

4. The acoustic wave device according to claim 3, wherein in a region overlapping with the reflector, a step is provided between a portion where the first protective film is provided but the load film is not provided and a portion where the load film and the first protective film are laminated.

5. The acoustic wave device according to claim 1, wherein the load film is provided between the first main surface of the piezoelectric layer and the reflector in the first direction of the piezoelectric layer.

6. The acoustic wave device according to claim 2, wherein
the protective film includes a first protective film provided on the first main surface of the piezoelectric layer to cover the IDT electrode, and a second protective film provided on the second main surface of the piezoelectric layer; and
the load film is provided on a surface of the second protective film facing the support.

7. The acoustic wave device according to claim 2, wherein
the protective film includes a first protective film provided on the first main surface of the piezoelectric layer to cover the IDT electrode, and a second protective film provided on the second main surface of the piezoelectric layer;
the load film is provided on the second main surface of the piezoelectric layer; and
the second protective film covers the load film.

8. The acoustic wave device according to claim 2, wherein
the protective film includes a first protective film provided on the first main surface of the piezoelectric layer to cover the IDT electrode and the reflector;
the load film is provided on the reflector; and
the first protective film covers the load film and the reflector.

9. The acoustic wave device according to claim 1, wherein
the reflector includes a plurality of reflective electrode fingers arranged in the arrangement direction;
each of the plurality of reflective electrode fingers extends along an extending direction of the electrode fingers of the IDT electrode; and
the load film is provided in a region overlapping with the plurality of reflective electrode fingers.

10. The acoustic wave device according to claim 1, wherein the load film includes a first extending portion provided in a region overlapping with the reflector, and an outer load film provided in a region outside the first extending portion in the arrangement direction and not overlapping with the reflector and the IDT electrode.

11. The acoustic wave device according to claim 2, wherein a film thickness of the protective film is smaller than a film thickness of the piezoelectric layer.

12. The acoustic wave device according to claim 1, wherein the IDT electrode is provided on both of the first main surface and the second main surface of the piezoelectric layer.

13. An acoustic wave filter device comprising:
at least one resonator including the acoustic wave device according to claim 1.

14. The acoustic wave filter device according to claim 13, further comprising:
an input terminal, an output terminal, a series arm connecting the input terminal and the output terminal, and a parallel arm connecting a node of the series arm and a ground; wherein
the at least one resonator includes a plurality of resonators that include a series arm resonator provided in the series arm and a parallel arm resonator provided in the parallel arm; and
the load film of the series arm resonator has a configuration different from that of the load film of the parallel arm resonator.

15. The acoustic wave device according to claim 1, wherein
the load film includes a first extending portion, a second extending portion, a third extending portion, and a fourth extending portion;
the first extending portion is provided in a region overlapping with a first reflector located outermost in the arrangement direction, and extends along an extending direction of the first reflector;
the second extending portion is provided in a region overlapping with a second reflector located outermost in the arrangement direction on a side opposite to the first extending portion, and extends along an extending direction of the second reflector;
the third extending portion is connected to one end side of the first extending portion and one end side of the second extending portion in the extending direction, and extends in the arrangement direction; and
the fourth extending portion is connected to another end side of the first extending portion and another end side of the second extending portion in the extending direction, and extends in the arrangement direction.

16. The acoustic wave device according to claim 1, wherein
the load film includes a first extending portion, a second extending portion, a third extending portion, and a fourth extending portion;
the first extending portion is provided in a region overlapping with a first reflector located outermost in the arrangement direction, and extends along an extending direction of the first reflector;
the second extending portion is provided in a region overlapping with a second reflector located outermost in the arrangement direction on a side opposite to the first extending portion, and extends along an extending direction of the second reflector;
the third extending portion is located on one end side of the first extending portion and one end side of the second extending portion in the extending direction, and extends in the arrangement direction;
the fourth extending portion is located on another end side of the first extending portion and another end side of the second extending portion in the extending direction, and extends in the arrangement direction; and
at least one of the third extending portion and the fourth extending portion is separate from the first extending portion and the second extending portion.

17. The acoustic wave device according to claim 2, wherein
the load film and the protective film include a same material; and
a density of the load film is different from a density of the protective film.

18. The acoustic wave device according to claim 2, wherein the protective film includes silicon oxide.

19. The acoustic wave device according to claim 1, wherein the piezoelectric layer includes lithium niobate or lithium tantalate, and has a 120°±10° rotated Y-cut or a 90°±10° rotated Y-cut.

20. The acoustic wave device according to claim 2, wherein the protective film includes a first protective film provided on the first main surface of the piezoelectric layer to cover the IDT electrode, and a second protective film provided on the second main surface of the piezoelectric layer.

21. The acoustic wave device according to claim 2, wherein a film thickness of the protective film is larger than a film thickness of the IDT electrode.

22. The acoustic wave device according to claim 20, wherein when A represents a sum of distances from a center of a film thickness of the piezoelectric layer to a top surface of the first protective film, and B represents a sum of distances from the center of the film thickness of the piezoelectric layer to a top surface of the second protective film, the value of A/B is about 1−0.06 or more and about 1+0.06 or less.

23. The acoustic wave device according to claim 20, wherein a top surface of the first protective film and a bottom surface of the second protective film are flat.

24. The acoustic wave device according to claim 1, wherein a material of the load film is at least one of carbon-added silicon oxide, silicon oxide, silicon nitride, tantalum oxide, aluminum nitride, aluminum oxide, hafnium oxide, niobium oxide, or tungsten oxide.

25. The acoustic wave device according to claim 1, wherein d/p is about 0.24 or less.

26. The acoustic wave device according to claim 1, wherein
a region where the adjacent electrode fingers overlap with each other when viewed from a direction perpendicular to the electrode fingers, and a region between the centers of the adjacent electrode fingers in the direction perpendicular to the electrode fingers are an excitation region; and
when MR represents a metallization ratio of the electrode fingers to the excitation region, MR≤about 1.75 (d/p)+0.075 is satisfied.

27. The acoustic wave device according to claim 1, wherein the piezoelectric layer includes lithium tantalate or lithium niobate.

28. The acoustic wave device according to claim 1, wherein Euler angles (φ, θ, ψ) of lithium niobate or lithium tantalate included in the piezoelectric layer satisfy a following Expression (1), (2), or (3):
(0°±10°, 0° to 20°, any ψ) . . . (1)
(0°±10°, 20° to 80°, 0° to 60° (1−(θ−50)²/900)^{1/2}) or (0°±10°, 20° to 80°, [180°-60° (1−(θ−50)²/900)^{1/2}] to 180°) . . . (2)
(0°±10°, [180°-30° (1−(ψ−90)²/8100)^{1/2}] to 180°, any ψ) . . . (3).

29. The acoustic wave device according to claim 1, wherein the acoustic reflection portion is a cavity portion, and the support and the piezoelectric layer are arranged such that a portion of the support and a portion of the piezoelectric layer face each other across the cavity portion.

30. The acoustic wave device according to claim 1, wherein the acoustic reflection portion is an acoustic reflection film that includes a high acoustic impedance layer with a relatively high acoustic impedance and a low acoustic impedance layer with a relatively low acoustic impedance, and the support and the piezoelectric layer are arranged such that at least a portion of the support and at least a portion of the piezoelectric layer face each other across the acoustic reflection film.
